(19) United States
(12) Patent Application Publication
(10) Pub. No.: US 2024/0242930 A1
(43) Pub. Date: Jul. 18, 2024

(54) MANIPULATION OF CARRIER TRANSPORT BEHAVIOR IN DETECTOR

(71) Applicant: ASML Netherlands B.V., Veldhoven (NL)

(72) Inventors: Jan BEX, Overpelt (BE); Nickolay STEPANENKO, Helmond (NL); Matthias OBERST, Nürnberg (DE); Harald Gert Helmut NEUBAUER, Erlangen (DE); Thomas SCHWEIGER, Nueremberg (DE); Florian Alfons STIEGLITZ, Bamberg (DE); Bernd Michael VOLLMER, Dresden (DE)

(21) Appl. No.: 18/563,841

(22) PCT Filed: May 18, 2022
(86) PCT No.: PCT/EP2022/063382

§ 371 Date: Nov. 22, 2023

Related U.S. Application Data
(60) Provisional application No. 63/194,137, filed on May 27, 2021.

(51) Int. Cl. H01J 37/244; G01T 1/24; G01T 1/29

(52) U.S. Cl. CPC H01J 37/244; G01T 1/24; G01T 1/2928; H01J 2237/2441

(57) ABSTRACT

A charged particle detector may include a plurality of sensing elements formed in a substrate, wherein a sensing element of the plurality of sensing elements is formed of a first region on a first side of the substrate, and a second region on a second side of the substrate, the second side being opposite to the first side. The detector may also include a plurality of third regions formed on the second side of the substrate, the third regions including one or more circuit components. The detector may also include an array of fourth regions formed on the second side of the substrate, the array of fourth regions being between adjacent third regions.

### CROSS-REFERENCE TO RELATED APPLICATIONS

This application claims priority of U.S. application 63/194,137 which was filed on 27 May 2021 and which is incorporated herein in its entirety by reference 8572.

### FIELD

The description herein relates to detectors, and more particularly, to detectors that may be applicable to charged particle detection.

### BACKGROUND

Detectors may be used for sensing physically observable phenomena. For example, charged particle beam tools, such as electron microscopes, may comprise detectors that receive charged particles projected from a sample and that output detection signals. Detection signals may be used to reconstruct images of sample structures under inspection and may be used, for example, to reveal defects in the sample. Detection of defects in a sample is increasingly important in the manufacturing of semiconductor devices, which may include large numbers of densely packed, miniaturized integrated circuit (IC) components. Inspection systems may be provided as dedicated tools for this purpose.

With continuing miniaturization of semiconductor devices, performance demands for inspection systems, including a detector, may continue to increase. Meanwhile, the detector may require flexibility for detecting one or more beams that may land on the detector with unknown sizes and at unknown positions. A detector array may be pixelated in an array of sensing elements that can adapt to different shapes and sizes of beams. Detection signals may be generated based on charge carriers that flow in each pixel and may be routed out through a readout path in each pixel. Existing detection systems may encounter issues with movement of charge carriers within the interior of the detector. Movement of charge carriers may be based on drift behavior or diffusion behavior. Improvements in detection systems and methods are desired.

### SUMMARY

Embodiments of the present disclosure provide systems and methods for detection based on charged particle beams. In some embodiments, there may be provided a charged particle beam system that includes a detector. A charged particle detector may include a plurality of sensing elements formed in a substrate, wherein a sensing element of the plurality of sensing elements is formed of a first region on a first side of the substrate, and a second region on a second side of the substrate, the second side being opposite to the first side. The detector may also include a plurality of third regions formed on the second side of the substrate, the third regions including one or more circuit components. The detector may also include an array of fourth regions formed on the second side of the substrate, the array of fourth regions being between adjacent third regions.

In some embodiments, a charged particle detector may include a plurality of sensing elements formed in a substrate, wherein a sensing element of the plurality of sensing elements is formed of a first region on a first side of the substrate, and a second region on a second side of the substrate, the second side being opposite to the first side. The detector may also include a plurality of third regions formed on the second side of the substrate, the third regions including one or more circuit components. The detector may also include a plurality of fourth regions formed on the second side of the substrate, a first portion of the plurality of fourth regions being connected to a first potential and a second portion of the plurality of fourth regions being connected to a second potential different from the first potential.

In some embodiments, a method for detecting charged particles may include illuminating a substrate that includes a portion of a detector to cause generation of carriers in the substrate, receiving, at the substrate, a charged particle emitted from a sample, wherein the charged particle interacts with the substrate to trigger generation of numerous carriers in the substrate, and detecting carriers via a pickup point on the substrate.

In some embodiments, a non-transitory computer-readable medium may be provided that stores a set of instructions that are executable by one or more processors of a charged particle beam apparatus to cause the charged particle beam apparatus to perform a method comprising: illuminating a substrate that includes a portion of a detector to cause generation of carriers in the substrate; receiving, at the substrate, a charged particle emitted from a sample, wherein the charged particle interacts with the substrate to trigger generation of numerous carriers in the substrate; and detecting carriers via a pickup point on the substrate.

In some embodiments, a charged particle detector may include a plurality of sensing elements formed in a substrate, wherein a sensing element of the plurality of sensing elements is formed of a first region on a first side of the substrate, and a second region on a second side of the substrate, the second side being opposite to the first side. The detector may also include a plurality of third regions formed on the second side of the substrate, the third regions including one or more circuit components. The detector may also include a fourth region formed on the second side of the substrate, the fourth region being configured to collect carriers generated in the sensing element. The second region includes a differential gradient region between a periphery of the sensing element and the fourth region.

It is to be understood that both the foregoing general description and the following detailed description are exemplary and explanatory only and are not restrictive of the disclosed embodiments, as may be claimed.

### BRIEF DESCRIPTION OF THE DRAWINGS

The above and other aspects of the present disclosure will become more apparent from the description of exemplary embodiments, taken in conjunction with the accompanying drawings.

FIG. 1 is a diagrammatic representation of an exemplary electron beam inspection (EBI) system, consistent with embodiments of the present disclosure.

FIGS. 2A and 2B are diagrams illustrating a charged particle beam apparatus that may be an example of an electron beam tool, consistent with embodiments of the present disclosure.

FIG. 3 is a diagrammatic representation of an exemplary structure of a detector, consistent with embodiments of the present disclosure.

FIG. 4 is a diagrammatic representation of a detector, consistent with embodiments of the present disclosure.

FIG. 5 is a diagrammatic representation of an individual sensing element of a detector, consistent with embodiments of the disclosure.

FIG. 6 is a diagrammatic representation of an individual sensing element of a detector operating with a depletion region, consistent with embodiments of the disclosure.

FIGS. 7A-7C illustrate a detector with pickup points, consistent with embodiments of the disclosure.

FIGS. 8A-8C illustrate examples of fourth regions of a detector, consistent with embodiments of the disclosure.

FIGS. 9A-9C illustrate examples of fourth regions of a detector, consistent with embodiments of the disclosure.

FIGS. 10A-10E illustrate examples of fourth regions of a detector, consistent with embodiments of the disclosure

FIGS. 11A-11D illustrate examples of patterns of fourth regions in a detector, consistent with embodiments of the disclosure.

FIGS. 12A-12C illustrate examples of patterns that may be used for pickup points and driver electrodes, consistent with embodiments of the disclosure.

FIG. 13 is a diagrammatic representation of attraction of carriers to pickup points, consistent with embodiments of the disclosure.

FIGS. 14A-14C illustrate examples of illumination provided by external sources, consistent with embodiments of the disclosure.

FIG. 15 which is a flowchart illustrating a method that may be useful for charged particle detection, consistent with embodiments of the disclosure.

FIGS. 16A and 16B illustrate differential gradients, consistent with embodiments of the disclosure.

### DETAILED DESCRIPTION

Reference will now be made in detail to exemplary embodiments, examples of which are illustrated in the drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses, systems, and methods consistent with aspects related to subject matter that may be recited in the appended claims.

Electronic devices are constructed of circuits formed on a piece of silicon called a substrate. Many circuits may be formed together on the same piece of silicon and are called integrated circuits or ICs. With advancements in technology, the size of these circuits has decreased dramatically so that many more of them can fit on the substrate. For example, an IC chip in a smart phone can be as small as a fingernail and yet may include over 2 billion transistors, the size of each transistor being less than 1/1,000th the width of a human hair.

Making these extremely small ICs is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). A SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur. To enhance throughput (e.g., the number of samples processed per hour), it is desirable to conduct inspection as quickly as possible.

An image of a wafer may be formed by scanning a primary beam of a SEM system (e.g., a “probe” beam) over the wafer and collecting particles (e.g., secondary electrons) generated from the wafer surface at a detector. Secondary electrons may form a beam (a “secondary beam”) that is directed toward the detector. Secondary electrons landing on the detector may cause electrical signals (e.g., current, charge, voltage, etc.) to be generated in the detector. These signals may be output from the detector and may be processed by an image processor to form the image of the sample.

A detector may include a pixelated array of multiple sensing elements. A pixelated array may be useful because it may allow adaptation to the size and shape of beam spots formed on the detector. When multiple primary beams are used, with multiple secondary beams incident on the detector, a pixelated array may be helpful to segregate different regions of the detector associated with different beam spots. Multiple beams may land on the detector with unknown sizes and at unknown positions, thus forming different beam spots that may cover different pixels (e.g., individual sensing elements) of the array.

A detector may include circuitry configured to process signals generated in individual sensing elements, such as a read-out integrated circuit (“ROIC”). The sensing elements may include one or more diodes that may convert incident energy into a measurable signal. Circuitry of the detector may include wiring paths configured to route signals to various locations or electrical components configured to perform particular functions. An electron beam spot may cover multiple sensing elements on the detector, and signals generated in the sensing elements may be routed together. Circuitry included in a detector may include a wiring path that routes output from individual sensing elements that are grouped together (e.g., by virtue of being covered by the same electron beam spot) to a common output. The circuitry may also include electrical components such as switches configured to connect sensing elements that are grouped together.

The detector may also include components for collecting output of each sensing element. Output may be collected at pickup points for each sensing element. For example, an electrode may be provided in each sensing element to collect output to be associated with a respective pixel. Output may be in the form of charge carriers that are generated in response to a charged particle arrival event occurring at a sensing element. For example, a sensing element in an electron detector may be formed as a semiconductor diode that generates numerous carriers (e.g., electron-hole pairs) when a secondary electron arrives at the sensing element. The carriers may be transported through the material making up the sensing element. Holes may travel toward one electrode (e.g., an anode), and electrons may travel toward another electrode (e.g., a cathode).

Output of a sensing element may be formed by carriers collected at the pickup point of the sensing element. To assist in extracting carriers from the interior of the sensing element, an electric field (e.g., a driver field) may be applied so that carriers are attracted to respective electrodes. However, an arrangement of a sensing element may impede efficient extraction of carriers.

In some arrangements, incoming secondary charged particles (e.g., secondary electrons) may approach a detector from a bottom side, while pickup points are located at a top side of the detector. A substantially vertical driver field may be applied between a common anode on the bottom side of the detector and individual cathodes acting as pickup points on the top side of the detector. The vertical direction may refer to the thickness direction of the detector. Carriers, such as electrons generated in the sensing element in response to a secondary electron arrival event, may be influenced by the field and migrate toward the pickup point (e.g., “drift” behavior). Electrons arriving at the pickup point may be collected, and signals are routed towards high-speed data acquisition electronics located close by the detector. But some electrons may be located in regions between pickup points (e.g., in the horizontal direction). Electrons may become stagnant in this area as there may be no horizontal field driving these electrons towards the pickup points. Such electrons may migrate by diffusion and may eventually arrive at pickup points, but slowly. Slow electron collection and detection behavior may negatively affect detector performance.

Some embodiments of the disclosure may address the above issues and may enhance carrier transport behavior in a detector. Detector speed and bandwidth may be enhanced.

In some embodiments, geometry of pickup points may be configured so as to enhance carrier transport. Areas in a detector provided for pickup points may be increased. Multiple pickup points may be provided for one sensing element. And pickup points may be enlarged relative to a comparative example. Pickup points may be broadened so that regions between adjacent pickup points where carriers may stagnate are reduced. More carriers generated in a sensing element may be influenced by a vertical driver field, and the path that the carriers take to the pickup point may be shortened.

In some embodiments, a horizontal driver field may be applied. Driver electrodes may be arranged adjacent to pickup points. Horizontal driver field may be generated between driver electrodes and pickup points, and carriers that may be located in regions between adjacent pickup points may be moved out of such regions and toward pickup points. Horizontal driver field may be applied together with vertical driver field. Thus, carriers may experience drift behavior in both directions, rather than relying only on diffusion in the horizontal direction. In some embodiments, some pickup points may have a different potential applied to them so as to provide a horizontal field between pickup points. In addition, distance between adjacent pickup points may be reduced.

In some embodiments, a second source of radiation (e.g., in addition to the secondary charged particles incident on the detector) may be used to illuminate a detector. The second source may generate a supply of free carriers in the detector. The detector may be saturated with free carriers such that when a secondary electron arrival event occurs, an immediate or faster response may be detected at pickup points. For example, an impulse of carriers may be delivered to a pickup point in response to a secondary electron arrival event. In some embodiments, a change in potential may be detected at the pickup point. The second source may be an electron beam, a laser, an LED, or any radiation source. The second source may act to pre-load sensing elements with carriers.

In some embodiments, a differential gradient may be provided in sensing elements. The differential gradient may be configured to generate a passive field to influence carriers. The differential gradient may be in the horizontal direction between pickup points. A sensing element may be constructed from a semiconductor substrate. A gradient of implants, such as stepped implant regions, may be used. The differential gradient may cause carriers in a region between pickup points to move toward the closest pickup point.

Objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

Without limiting the scope of the present disclosure, some embodiments may be described in the context of providing detection systems and detection methods in systems utilizing electron beams (“e-beams”). However, the disclosure is not so limited. Other types of charged particle beams may be similarly applied. Furthermore, systems and methods for detection may be used in other imaging systems, such as optical imaging, photon detection, x-ray detection, ion detection, etc.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A. B. or C, then, unless specifically stated otherwise or infeasible, the component may include A. or B, or C, or A and B, or A and C, or B and C, or A and B and C. Expressions such as “at least one of” do not necessarily modify an entirety of a following list and do not necessarily modify each member of the list, such that “at least one of A. B. and C” should be understood as including only one of A, only one of B, only one of C, or any combination of A, B, and C. The phrase “one of A and B” or “any one of A and B” shall be interpreted in the broadest sense to include one of A, or one of B.

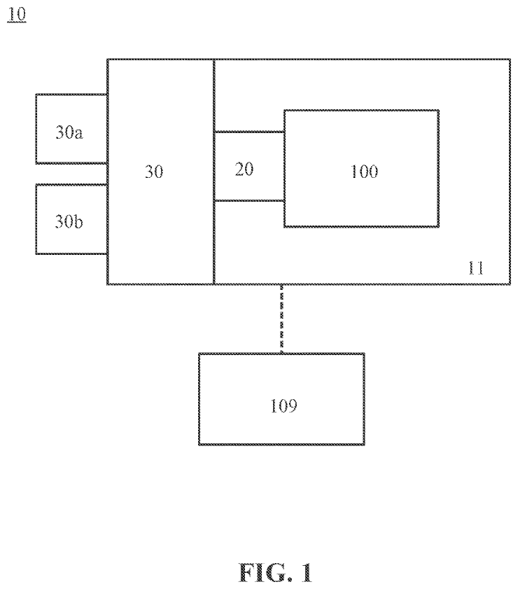

Reference is now made to FIG. 1, which illustrates an exemplary electron beam inspection (EBI) system 10 that may be used for wafer inspection, consistent with embodiments of the present disclosure.

As shown in FIG. 1. EBI system 10 includes a main chamber 11 a load/lock chamber 20, an electron beam tool 100 (e.g., a scanning electron microscope (SEM)), and an equipment front end module (EFEM) 30. Electron beam tool 100 is located within main chamber 11 and may be used for imaging. EFEM 30 includes a first loading port 30a and a second loading port 30b. EFEM 30 may include additional loading ports. First loading port 30a and second loading port 30b receive wafer front opening unified pods (FOUPs) that contain wafers (e.g., semiconductor wafers or wafers made of other materials) or samples to be inspected (wafers and samples may be collectively referred to as “wafers” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to inspection by electron beam tool 100. Electron beam tool 100 may be a single-beam system or a multi-beam system. A controller 109 is electronically connected to electron beam tool 100, and may be electronically connected to other components as well. Controller 109 may be a computer configured to execute various controls of EBI system 10. While controller 109 is shown in FIG. 1 as being outside of the structure that includes main chamber 11, load/lock chamber 20, and EFEM 30, it is appreciated that controller 109 can be part of the structure.

A charged particle beam microscope, such as that formed by or which may be included in EBI system 10, may be capable of resolution down to, e.g., the nanometer scale, and may serve as a practical tool for inspecting IC components on wafers. With an e-beam system, electrons of a primary electron beam may be focused at probe spots on a sample (e.g., a wafer) under inspection. The interactions of the primary electrons with the wafer may result in secondary particle beams being formed. The secondary particle beams may comprise backscattered electrons, secondary electrons, or Auger electrons, etc. resulting from the interactions of the primary electrons with the wafer. Characteristics of the secondary particle beams (e.g., intensity) may vary based on the properties of the internal or external structures or materials of the wafer, and thus may indicate whether the wafer includes defects.

The intensity of the secondary particle beams may be determined using a detector. The secondary particle beams may form beam spots on a surface of the detector. The detector may generate electrical signals (e.g., a current, a charge, a voltage, etc.) that represent intensity of the detected secondary particle beams. The electrical signals may be measured with measurement circuitries which may include further components (e.g., analog-to-digital converters) to obtain a distribution of the detected electrons. The electron distribution data collected during a detection time window, in combination with corresponding scan path data of the primary electron beam incident on the wafer surface, may be used to reconstruct images of the wafer structures or materials under inspection. The reconstructed images may be used to reveal various features of the internal or external structures or materials of the wafer and may be used to reveal defects that may exist in the wafer.

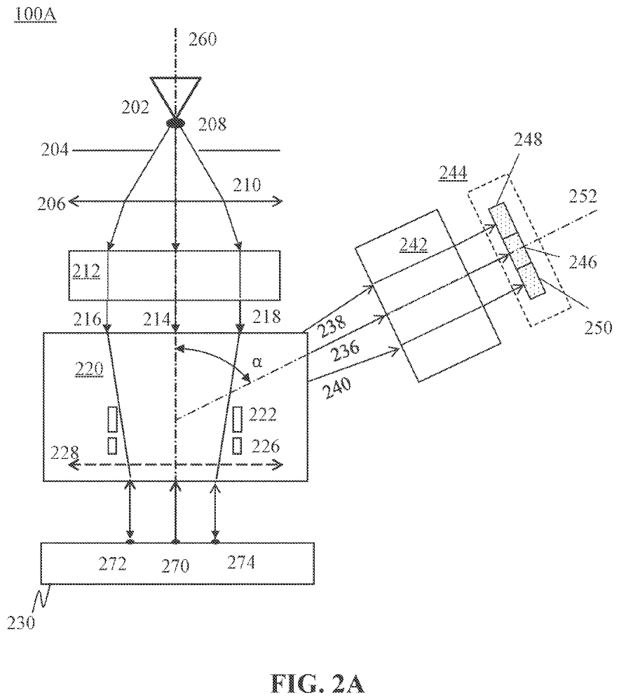

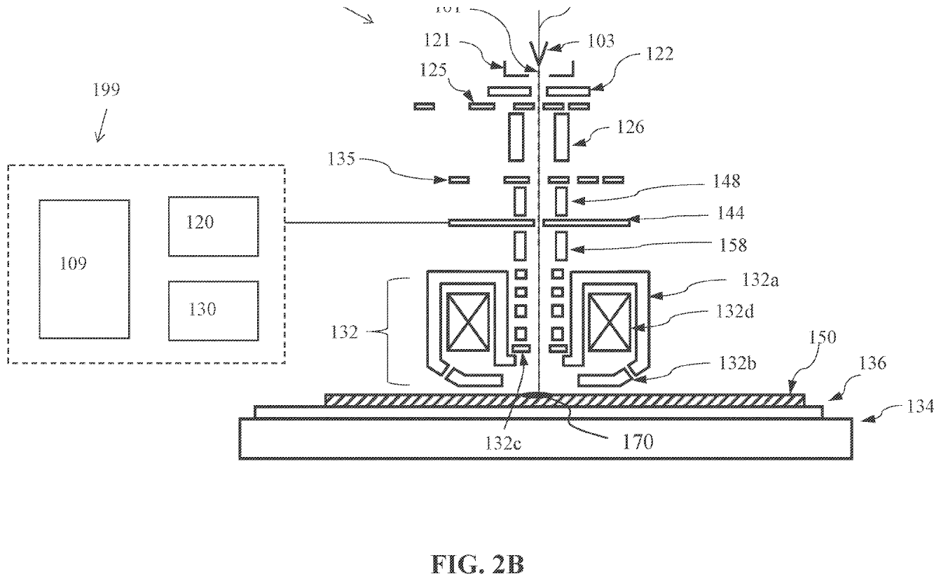

FIG. 2A illustrates a charged particle beam apparatus that may be an example of electron beam tool 100, consistent with embodiments of the present disclosure. FIG. 2A shows an apparatus that uses a plurality of beamlets formed from a primary electron beam to simultaneously scan multiple locations on a wafer.

As shown in FIG. 2A, electron beam tool 100A may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2A), multiple secondary electron beams 236, 238, and 240, a secondary optical system 242, and electron detection device 244. Electron source 202 may generate primary particles, such as electrons of primary electron beam 210. A controller, image processing system, and the like may be coupled to electron detection device 244. Primary projection optical system 220 may comprise beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of apparatus 100A. Secondary optical system 242 and electron detection device 244 may be aligned with a secondary optical axis 252 of apparatus 100A.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2A) and an array of beam-limit apertures (not shown in FIG. 2A). An example of source conversion unit 212 may be found in U.S. Pat. No. 9,691,586; U.S. Publication No. 2017/0025243; and International Application No. PCT/EP2017/084429, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be an adjustable condenser lens that may be configured so that the position of its first principal plane is movable. The adjustable condenser lens may be configured to be magnetic, which may result in off-axis beamlets 216 and 218 landing on the beamlet-limit apertures with rotation angles. The rotation angles change with the focusing power and the position of the first principal plane of the adjustable condenser lens. In some embodiments, the adjustable condenser lens may be an adjustable anti-rotation condenser lens, which involves an anti-rotation lens with a movable first principal plane. An example of an adjustable condenser lens is further described in U.S. Publication No. 2017/0025241, which is incorporated by reference in its entirety.

Objective lens 228 may focus beamlets 214, 216, and 218 onto a wafer 230 for inspection and may form a plurality of probe spots 270, 272, and 274 on the surface of wafer 230. Secondary electron beamlets 236, 238, and 240 may be formed that are emitted from wafer 230 and travel back toward beam separator 222.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over an area on a surface of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of the surface of wafer 230. Detection sub-regions 246, 248, and 250 may include separate detector packages, separate sensing elements, or separate regions of an array detector. In some embodiments, each detection sub-region may include a single sensing element.

Another example of a charged particle beam apparatus will now be discussed with reference to FIG. 2B. An electron beam tool 100B (also referred to herein as apparatus 100B) may be an example of electron beam tool 100 and may be similar to electron beam tool 100A shown in FIG. 2A. However, different from apparatus 100A, apparatus 100B may be a single-beam tool that uses only one primary electron beam to scan one location on the wafer at a time.

As shown in FIG. 2B, apparatus 100B includes a wafer holder 136 supported by motorized stage 134 to hold a wafer 150 to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In a detection or imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as image averaging, generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses may be used for controlling the electron beam. For example, first quadrupole lens 148 may be controlled to adjust the beam current and second quadrupole lens 158 may be controlled to adjust the beam spot size and beam shape.

FIG. 2B illustrates a charged particle beam apparatus that may use a single primary beam configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150. FIG. 2B shows an example of detector 144 having an opening at its center. However, some embodiments may use a detector placed off-axis relative to the optical axis along which the primary electron beam travels. For example, as in the embodiment shown in FIG. 2A, discussed above, a beam separator 222 may be provided to direct secondary electron beams toward a detector placed off-axis. Beam separator 222 may be configured to divert secondary electron beams by an angle α toward an electron detection device 244, as shown in FIG. 2A.

A detector in a charged particle beam system may include one or more sensing elements. The detector may comprise a single-element detector or an array with multiple sensing elements. The sensing elements may be configured to detect charged particles in various ways. The sensing elements may be configured for charged particle counting. Sensing elements of a detector that may be useful for charged particle counting are discussed in U.S. Publication No. 2019/0378682, which is incorporated by reference in its entirety. In some embodiments, sensing elements may be configured for signal level intensity detection.

Sensing elements may include a diode or an element similar to a diode that may convert incident energy into a measurable signal. For example, sensing elements in a detector may include a PIN diode. Throughout this disclosure, sensing elements may be represented as a diode, for example in certain figures, although sensing elements or other components may deviate from ideal circuit behavior of electrical elements such as diodes, resistors, capacitors, etc.

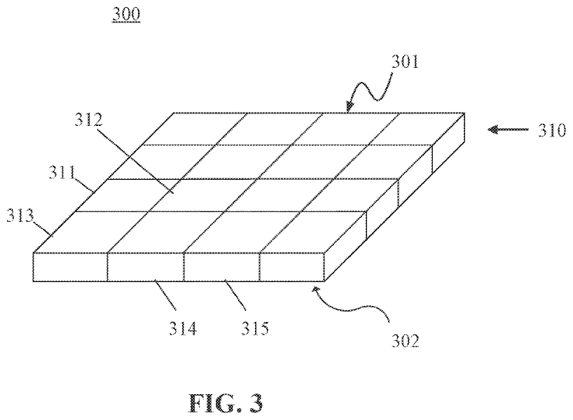

FIG. 3 illustrates an exemplary structure of a detector 300, consistent with embodiments of the present disclosure. Detector 300 may include an array of sensing elements. Detector 300 may include a 2-dimensional (2D) pixelated array. A detector such as detector 300 shown in FIG. 3 may be provided as charged-particle detection device 244 as shown in FIG. 2A or detector 144 as shown in FIG. 2B. In FIG. 3, detector 300 includes a sensor layer 310. In some embodiments, a separate signal processing layer may be provided, or a signal processing layer may be integrated in sensor layer 310 (e.g., in a monolithic layer). Sensor layer 310 may include a sensor die made up of multiple sensing elements, including sensing elements 311, 312, 313, 314, and 315. In some embodiments, the multiple sensing elements may be provided in an array of sensing elements, the sensing elements having a uniform size, shape, and arrangement. Detector 300 may be formed as a semiconductor substrate having a first surface 301 and a second surface 302. First surface 301 may act as a detection surface 301 that is configured to receive charged particles. Second surface 302 may be on an opposite side of first surface 301. There may be multiple sensing elements formed in first surface 301, each of the sensing elements configured to receive charged particles emitted from a sample. Circuitry or other electrical components, such as an electrode or wiring path, may be formed on second surface 302. Furthermore, signal processing components, such as transistors, may be formed on second surface 302.

Each of sensing elements 311, 312, 313, 314, and 315 may be configured to generate a response to a charged particle event. For example, sensing element 311 may be configured to absorb energy deposited thereon by a particle (e.g., an incoming secondary electron) and generate carriers (e.g., electron-hole pairs) that are swept to electrodes of sensing element 311 by an electric field. The carriers may be generated within the sensing element and may be fed to circuitry connected to the sensing element, including readout circuitry. In some embodiments, the circuitry may be integrated within a monolithic layer of a detector. In some embodiments, the circuitry may be provided in a separate die that includes a signal processing layer.

A signal processing layer may include a read-out integrated circuit (ROIC). The signal processing layer may include multiple signal processing circuits. The signal processing circuits may include interconnections or wiring paths configured to communicatively couple sensing elements. Each sensing element of sensor layer 310 may have a corresponding signal processing circuit in the signal processing layer. Sensing elements and their corresponding circuits may be configured to operate independently. Sensing elements may rout signals to the signal processing layer through an electrode formed on second surface 302 of detector 300.

A signal processing layer may include circuit components configured to perform charged particle detection. For example, the signal processing layer may include an amplifier, logical components, switches, and any component configured to perform signal processing.

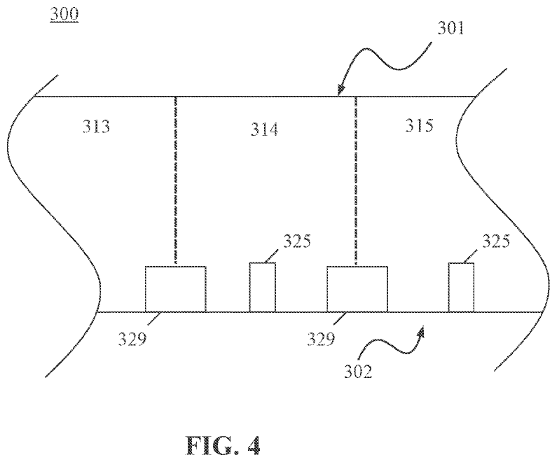

Reference is now made to FIG. 4, which is a diagrammatic representation of a side view of a detector, consistent with embodiments of the disclosure. FIG. 4 may represent a partial cross section of detector 300 showing interior regions of sensing elements and other components.

As shown in FIG. 4, detector 300 may include a layer of sensing elements, including sensing elements 313, 314, and 315. Although a partition is shown in FIG. 4 between different sensing elements with a dashed line, such partition may not physically be present in detector 300. In some embodiments, insulation may be provided between adjacent sensing elements. However, in some embodiments, detector 300 may be formed with a continuous region of semiconductor substrate. Sensing elements 313, 314, and 315 may be contiguous with one another.

Detector 300 may be configured to both receive charged particles and route output signals. Detector 300 may include a pixelated array of sensing elements and integrated circuitry. Components may be provided in second surface 302 of detector 300.

Components provided in second surface 302 may include electrodes, wiring paths, and transistors, for example. As shown in FIG. 4, detector 300 includes electrodes 325 and transistors 329. Electrode 325 may be configured as a collection electrode. Electrode 325 may be configured to output signals in response to charged particle arrival events occurring at detector 300. Electrode 325 may also be referred to as a pickup point or substrate tap. Carriers generated in a region of a particular sensing element may be collected at electrode 325. Carriers may be read out to other components, such as signal processing components. Carriers may make up an output signal, such as beam current, that may be used in detection of charged particles. Electrode 325 may be configured as a cathode. Detection surface 301 may be formed as an electrode (e.g., a thin conductive layer) and may be configured as an anode. A common anode may be formed on multiple sensing elements. Detection surface 301 may include the common anode. Individual cathodes may be provided for each sensing element.

Transistor 329 may be configured as a switch. Transistor 329 may be configured to connect adjacent sensing elements. Sensing elements may be connected in accordance with a grouping that may correspond with a single electron beam spot covering multiple sensing elements. Transistor 329 may be provided for other purposes. Furthermore, multiple transistors may be provided in second surface 302. The view of FIG. 4 may be only a cross section at a particular point, and detector 300 may have different structures formed in second surface 302 at different cross sections.

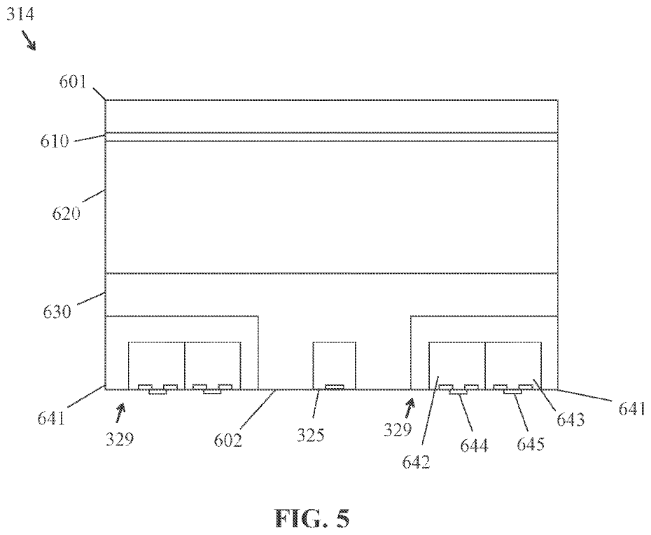

Reference is now made to FIG. 5, which is a diagrammatic representation of an individual sensing element of a detector, consistent with embodiments of the disclosure. FIG. 5 may represent a partial cross section of detector 300 showing an interior of sensing element 314. Sensing element 314 may be formed from a semiconductor substrate. Sensing element 314 may be configured to have a plurality of regions arranged in a thickness direction, the thickness direction being substantially parallel to an incidence direction of a charged particle beam. For example, an electron beam may be incident on detector 300 at detection surface 301. The plurality of regions of sensing element 314 may include regions sensitive to charged particles. In response to an arrival of a charged particle in sensing element 314, numerous carriers may be generated in an interior region of sensing element 314, and the carriers may be collected at another region. For example, carriers may be collected at electrode 325 and may be output to other components that may perform signal processing.

Sensing element 314 may be configured as a diode. Sensing element 314 may be formed using semiconductor processing, such as CMOS processes. Various regions of sensing element 314 may be formed by embedding regions into a substrate. The embedded regions may include dopants. Sensing element 314 may include semiconductor regions including a surface layer 601, a shallow p+ region 610, and a p epitaxial region 620. Surface layer 601 may be configured as a contact. Surface layer 601 may include or function similar to detection surface 301 (see FIGS. 3-4). Sensing element 314 may include a low dose n type implant region 630. Furthermore, electrode 325 and transistors 329 may also be provided that may be integrated with sensing element 314. Transistors 329 may include a deep p well 641, an n well 642, and a p well 643. A PMOS 644 and an NMOS 645 may be formed. Sensing element 314 may be configured so that a depletion region forms therein.

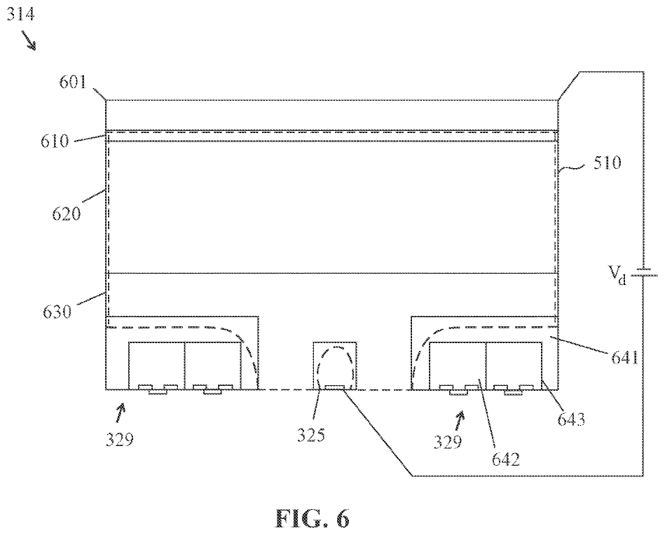

FIG. 6 is a diagrammatic representation of an individual sensing element of a detector operating with a depletion region, consistent with embodiments of the disclosure. A depletion region may be formed when a bias is applied to a sensing element. As shown in FIG. 6, a depletion region may be formed in sensing element 314 with boundaries of the depletion region indicated by dashed line 510. Boundaries of the depletion region may include region 610, electrode 625, and deep p well 641. The depletion region may be formed when driving voltage V_{d} is applied across surface layer 601 and electrode 325.

As shown in FIG. 5, a first side of sensing element 314 may be formed by surface layer 601. A second side 602 may also be formed. Second side 602 may be opposite from the first side. Signal processing or other components may be formed on second side 602. A first layer of a detector that includes sensing element 314 may include surface layer 601, region 610, p epitaxial region 620, and low dose n type implant region 630. A second layer of the monolithic detector may include transistors 329 and electrode 325. The first layer may correspond to a sensor layer, and the second layer may correspond to a signal processing layer. An insulator may include deep p well 641.

In operation of a charged particle beam apparatus, a primary electron beam may be projected onto a sample, and secondary particles including secondary electrons or backscattered electrons may be directed from the sample to sensing element 314. Sensing element 314 may be configured so that an incoming electron generates carriers including electron-hole pairs in p epitaxial region 620. Numerous electron-hole pairs may be generated due to a mechanism triggered by the arrival of an incoming electron, such as impact ionization. Electrons or holes of the electron hole pairs may flow to electrode 325 and may form a current pulse in response to the incoming electron arriving at sensing element 314. Signal processing components may process the current pulse.

Transistor 329 may be configured as a switching element. Transistor 329 may include a MOSFET. Transistor 329 may be used to connect sensing elements. Transistor 329 may demareate the boundaries between sensing elements. For example, the region between transistors 329 shown in FIG. 5 may correspond to sensing element 314, while regions between other transistors may correspond to other sensing elements, including sensing element 312, 313, and 315. Each of sensing elements 311, 312, 313, 314, 315 may comprise outputs for making electrical connections to other components. Outputs may be integrated with transistor 329 or may be provided separately. Outputs may be integrated in region 630 at other cross-sectional locations not shown in FIG. 5.

Although FIGS. 3-4 depict sensing elements 311, 312, 313, 314, and 315 as discrete units when viewed from the side, such divisions may not actually be present. For example, the sensing elements of a detector may be formed by a semiconductor device constituting a PIN diode device manufactured as a substrate with a plurality of regions including a p+ region, an intrinsic region, and an n+ region. Sensing elements 311, 312, 313, 314, and 315 may be contiguous in a transverse direction (e.g., a direction perpendicular to the thickness direction). Other components may also be provided that may be integral with the sensing elements.

A sensing element formed in a detector may be configured to generate a signal, such as an amplified charge or current, based on a received charged particle. The sensing element may be one of multiple sensing elements that may be formed on the first side of the detector. The sensing element may be configured to generate carriers in proportion to a first property of the received charged particle, such as an energy level. The carriers may form the signal that is output from the sensing element. An amplification mechanism such as impact ionization may cause numerous carriers to be generated. The amplified charge or current may be formed by the carriers being swept to an electrode of the detector. The electrode may be associated with the sensing element. For example, in FIG. 5, carriers generated in sensing element 314 may be swept to electrode 325, and an amplified charge or current may be output from electrode 325. Each sensing element may have its own electrode that may be formed on the second side of the detector.

However, issues may be encountered in transport mechanisms for moving carriers to respective electrodes. Incoming electrons may approach the detector from the first side, while pickup points (e.g., electrodes) are positioned at the second, opposite side of the detector. In some embodiments, carriers may be actively induced to move toward the pickup points. For example, drift behavior may be used to push carriers towards the second side of the detector using a vertical driver field. The driver field may be generated by applying a voltage between an anode located at the first side of the detector and cathodes forming pickup points at the second side of the detector. Carriers reaching the pickup point may be collected and sensing element output signals may be routed towards high-speed data acquisition electronics of the detector.

In some embodiments, a detector may be configured to have at least a predetermined bandwidth. For example, in some embodiments, target bandwidth for electron detection may be on the order of MHz. A target bandwidth range may be about 15-18 MHZ. In some embodiments, a target bandwidth may be about 140 MHZ. However, carrier transport behavior in a detector may impede the detector from achieving a certain bandwidth. For example, in some arrangements, areas between pickup points may be a problematic area related to speed because carriers (e.g., electrons) may get stuck in this area as there is no horizontal field driving these electrons towards the pickup points. This may cause slow electron detection behavior (slow diffusion behavior as opposed to fast drift behavior).

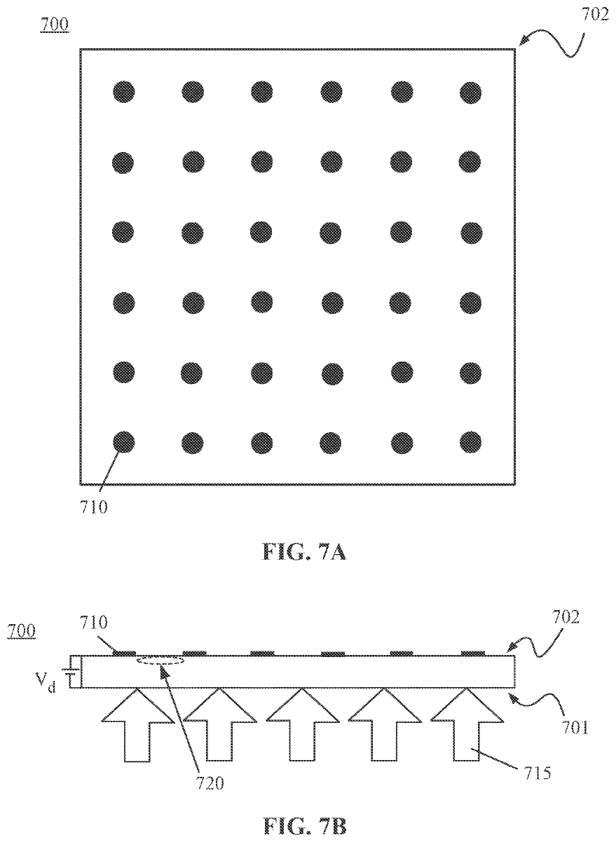

Reference is now made to FIG. 7A and FIG. 7B, which illustrate a detector with pickup points, consistent with embodiments of the disclosure. FIG. 7A is a plan view of a detector 700. Detector 700 may be similar to detector 300. FIG. 7B is a side view of detector 700. Detector 700 may have a first surface 701 and a second surface 702. First surface 701 may act as a detection surface that is configured to receive charged particles, similar to first surface 301 of detector 300 discussed above with reference to FIG. 3. Circuitry, signal processing components, or other electrical components may be formed on second surface 702, similar to second surface 302 of detector 300. As shown in FIG. 7A and FIG. 7B, detector 700 may include a plurality of pickup points 710. Pickup points 710 may be formed in second surface 702.

In operation, driving voltage V_{d} may be applied to detector 700. First surface 701 may include a conductive layer that may act as an anode. Pickup points 710 formed in second surface 702 may act as cathodes. Driving voltage V_{d} may be applied between first surface 701 and one or more of pickup points 710. A driver field may be formed that influences carriers generated in detector 700 to move toward pickup points 710. For example, an electric field may be formed using driving voltage V_{d} in a substantially vertical direction. The vertical direction may be in the thickness direction of detector 700. The vertical direction may be parallel to an incidence direction of secondary charged particles that detector 700 is configured to detect. For example, as shown in FIG. 7B, detector 700 may be configured to receive charged particles 715 on first surface 701. Charged particles 715 may include incoming secondary electrons emitted from a sample.

When secondary charged particles, such as secondary electrons, enter detector 700 at the frontside (e.g., at first surface 701), the secondary charged particles may generate many carriers (e.g., electron/hole pairs) in detector 700 and the carriers may be swept in certain directions. For example, electrons among the electron/hole pairs may be swept to the backside of detector 700 via an electric field that runs from the frontside to the backside (e.g., due to driving voltage V_{d}). The electric field may cause electrons to move vertically toward pickup points 710. Such transport behavior may be referred to as drift behavior. However, with no lateral field, electrons may pile-up at certain points and may only slowly migrate to a pickup point 710 via diffusion. As shown in FIG. 7B, there may be regions 720 where carriers may stagnate. Drift behavior induced by driving voltage V_{d} in the vertical direction may not be effective in moving carriers in regions 720 toward pickup points 710.

In some embodiments of the disclosure, properties of a detector, such as geometry, may be configured so that carrier transport behavior is manipulated. Properties of pickup points may be configured so that carriers migrate toward the pickup points more effectively. Pickup points may be broadened so that a greater proportion of area on the detector backside is covered by pickup points. In some embodiments, electron pile-up may be reduced by reducing resistance for carriers to reach backside tap points of a detector. A detector may be configured to fill in open areas on the backside of the detector backside substrate taps (pickup points). In some embodiments, speed of a detector may be improved.

FIG. 7C shows another view of detector 700, consistent with embodiments of the disclosure. In the view of FIG. 7C, individual sensing elements may be indicated with dashed lines. For example, detector 700 may include sensing elements 713, 714, and 715 that may be similar to sensing elements 313, 314, and 315 discussed above with reference to FIG. 3. As shown in FIG. 7C, each of the sensing elements of detector 700 may include a respective pickup point 710. Carriers generated within each sensing element may tend to migrate toward a respective pickup point 710 included in the sensing element.

In some embodiments of the disclosure, parameters of a detector may be configured so as to enhance carrier transport. For example, geometry of pickup points may be configured so as to enhance carrier transport. Areas in a detector provided for pickup points may be increased. Multiple pickup points may be provided for one sensing element. For example, an array of pickup points may be provided for each sensing element in the detector. Furthermore, pickup points may be enlarged relative to a comparative example. Pickup points may be broadened so that regions between adjacent pickup points where carriers may stagnate are reduced. Parameters of a detector may be configured so that occupancy ratio of pickup points in a sensing element is greater than or equal to a predetermined value.

In some embodiments, a charged particle detector may be provided. The charged particle detector may include an electron detector device. The charged particle detector may include a two-dimensional (2D) pixelated detector array. The charged particle detector may be formed in a semiconductor substrate. The charged particle detector may be formed on a wafer.

The charged particle detector may include a sensing element. A plurality of sensing elements may be provided. The plurality of sensing elements may be arranged in a 2D array. The sensing elements may be configured to generate carriers in response to a charged particle arrival event. The sensing elements may be formed as a PIN diode. Carriers in a sensing element may be swept to a pickup point.

With reference to FIG. 5, a sensing element of a detector consistent with embodiments of the disclosure may include sensing element 314. A detector may include a plurality of sensing elements, like detector 300 including sensing elements 311, 312, 313, 314, and 315, discussed above with reference to FIG. 3. Sensing element 314 may be formed of a first region. The first region may include a semiconductor material of a first conductivity. The first region may include p-type semiconductor. For example, as shown in FIG. 5, there may be a first region of sensing element 314 that includes region 610. Region 610 may be a shallow p+ region. The first region may also include surface layer 601 or p epitaxial region 620. The first region may be formed on a first side of the substrate forming the detector. As shown in FIG. 5, surface layer 601 may form a charged particle detection surface upon which incoming charged particles are incident. Secondary electrons may enter sensing element 314 from surface layer 601.

Opposite to the first side, the substrate may include a second side. For example, as shown in FIG. 5, sensing element 314 may include second side 602. Sensing element 314 may be formed of a second region that is formed on the second side of the substrate. The second region may include a semiconductor material of a second conductivity. The second region may include n-type semiconductor. For example, as shown in FIG. 5, there may be a second region of sensing element 314 that includes region 630. Region 630 may be a low dose n type implant region. The second region may be adjacent to the first region. For example, the first region may be formed in the first side of the substrate that may coincide with surface layer 601, and the second region may be formed on second side 602.

Furthermore, sensing element 314 may be formed of third regions on the second side. One or more circuit components may be formed in the third regions on the second side. For example, as shown in FIG. 5, transistor 329 may be formed on second side 602. Transistor 329 may be included in the third region. Multiple components may be formed on second side 602. For example, as shown in FIG. 5, two transistors 329 are formed on second side 602, one on the left side and one on the right side. The one or more components may be formed in one or more third regions. The third regions may include semiconductor material of the first type (e.g., p-type semiconductor). For example, as shown in FIG. 5, the third regions may include deep p wells 641. Components such as PMOS 644 and NMOS 645 may be formed in the third regions.

Furthermore, a fourth region may also be formed on the second side. The fourth region may be formed between adjacent third regions. The fourth region may include an electrode, pickup point, or substrate tap. For example, as shown in FIG. 5, the fourth region may include electrode 325. The fourth region may include semiconductor material of the second type (e.g., n-type semiconductor). In some embodiments, a parameter of the fourth region may be configured so as to enhance carrier transport in the detector. The parameter may include geometry of the fourth region. In some embodiments, an array of fourth regions may be provided. Multiple arrays of fourth regions may be provided in the detector. An array of fourth regions may be provided in each sensing element. In some embodiments, rather than an array, the fourth region may include a continuous region formed in an area between the third regions. The continuous regions may have an expanded area relative to a comparative example. In some embodiments, continuous regions may be combined with arrays.

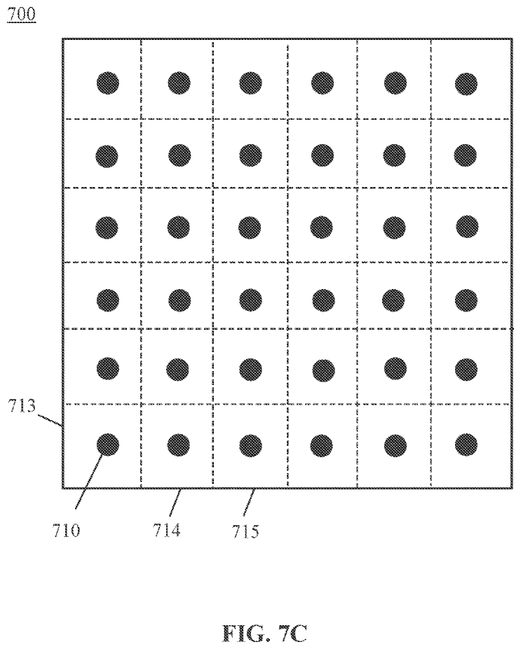

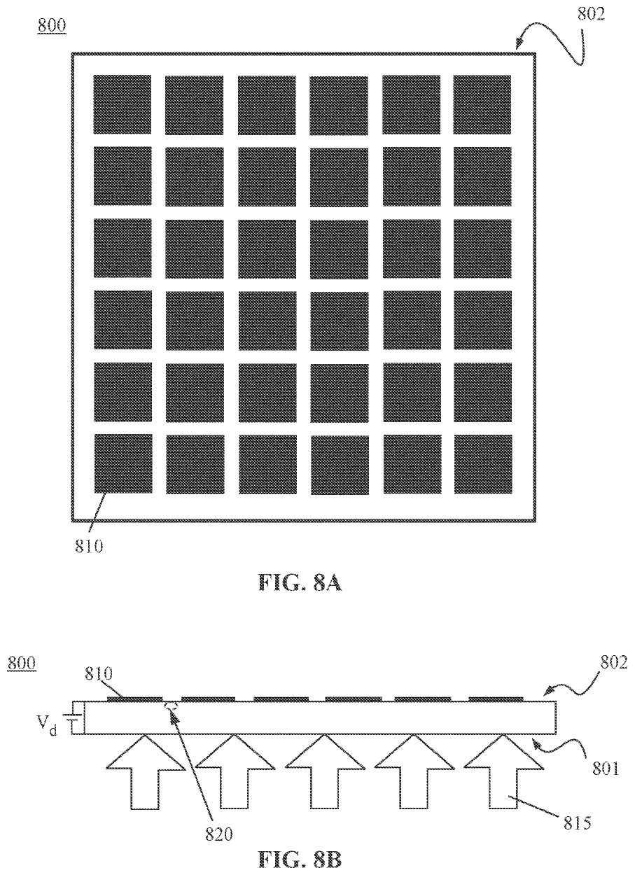

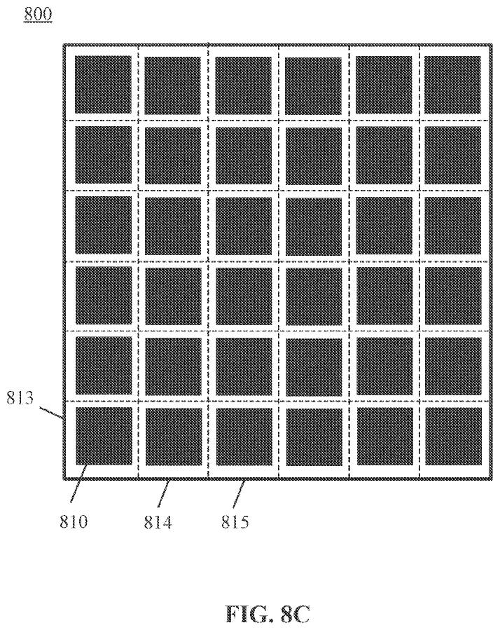

Reference is now made to FIG. 8A and FIG. 8B, which illustrate examples of fourth regions, consistent with embodiments of the disclosure. The fourth regions may include pickup points. FIG. 8A is a plan view of a detector 800. Detector 800 may be similar to detector 300 or detector 700. FIG. 8B is a side view of detector 800. Detector 800 may have a first surface 801 and a second surface 802. First surface 801 may act as a detection surface that is configured to receive charged particles, similar to first surface 301 of detector 300 discussed above with reference to FIG. 3. Circuitry, signal processing components, or other electrical components may be formed on second surface 802, similar to second surface 302 of detector 300. As shown in FIG. 8A and FIG. 8B, detector 800 may include a plurality of pickup points 810. Pickup points 810 may be formed in second surface 802. Pickup points 810 may be relatively larger than pickup points 710 discussed above with reference to FIG. 7A and FIG. 7B.

As shown in FIG. 8B, in operation, driving voltage V_{d} may be applied to detector 800. First surface 801 may include a conductive layer that may act as an anode. First surface 801 may include or be included in surface layer 601, discussed above with reference to FIG. 5. Pickup points 810 formed in second surface 802 may act as cathodes. Driving voltage V_{d} may be applied between first surface 801 and one or more of pickup points 810. A driver field may be formed that influences carriers generated in detector 800 to move toward pickup points 810. Detector 800 may be configured to receive charged particles 815 on first surface 801.

Secondary charged particles entering detector 800 at its frontside (e.g., at first surface 801) may generate many carriers (e.g., electron/hole pairs) in detector 800, and the carriers may be swept in certain directions. Carriers (e.g., electrons among the electron/hole pairs) may be swept to the backside of detector 800 via a driver field (e.g., an electric field) that runs from the frontside to the backside (e.g., due to driving voltage V_{d}). The driver field may cause electrons to move vertically toward pickup points 810. Electrons may be caused to move toward fourth regions. The fourth regions may include pickup points 810. As shown in FIG. 8B, substantially all of the area of second surface 802 may be occupied by pickup points 810. The driver field causing electrons to move vertically may allow greater proportions of electrons to quickly move to pickup points 810 by drift behavior and be collected for signal readout. In some embodiments, substantially all of the carriers generated in detector 800 by charged particle arrival events may be collected by pickup points 810 through drift behavior. Regions 820 where carriers may stagnate may be substantially reduced.

Reference is now made to FIG. 8C, which shows another view of detector 800, consistent with embodiments of the disclosure. In the view of FIG. 8C, individual sensing elements may be indicated with dashed lines. The dashed lines may demareate boundaries of sensing elements. The dashed lines may overlap with third regions of a sensing element (not shown in FIG. 8C). As shown in FIG. 8C, detector 800 may include sensing elements 813, 814, and 815 that may be similar to sensing elements 313, 314, and 315 discussed above with reference to FIG. 3. As shown in FIG. 8C, each of the sensing elements of detector 800 may include a respective pickup point 810. Sensing elements may be configured so that an occupancy ratio of pickup point 810 to a total area of a sensing element may be achieved. In some embodiments, an occupancy ratio of pickup points to total sensing element area may be greater than or equal to 50%. In some embodiments, an occupancy ratio may be greater than or equal to 75%. In some embodiments, an occupancy ratio may be greater than or equal to 90%.

In a comparative example, such as that of FIG. 7C, occupancy of pickup points 710 to total sensing element area may be relatively low. A majority of the area of each sensing element may be unpopulated by electrical components, such as electrodes and transistors. In some embodiments of the disclosure, this unpopulated area may be filled with an expanded area pickup point. For example, as shown in FIG. 8C, pickup points 810 may be broadened. Pickup points 810 may be configured as a low ohmic path. Pickup points 810 may provide a high speed path for carriers generated within sensing elements to be swept to collection electrodes. Carriers arriving at pickup points 810 may form an output signal of each sensing element.

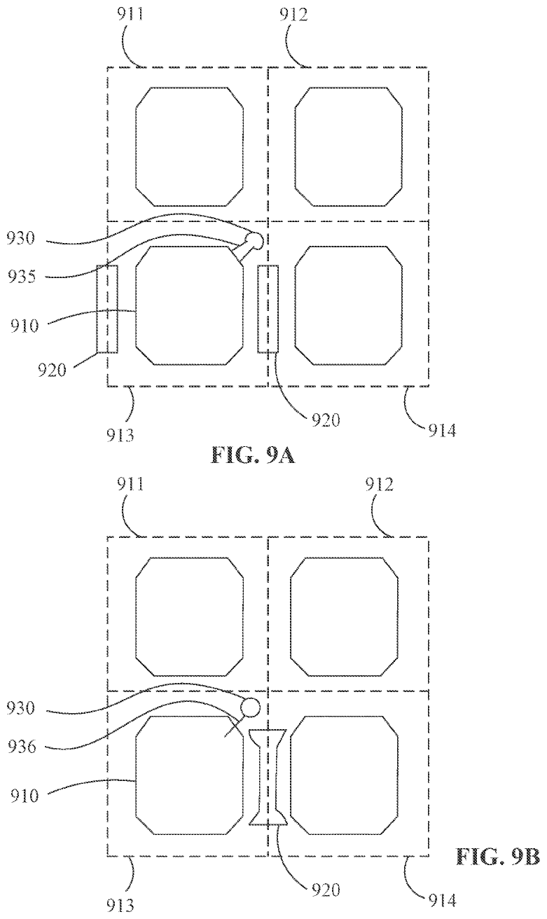

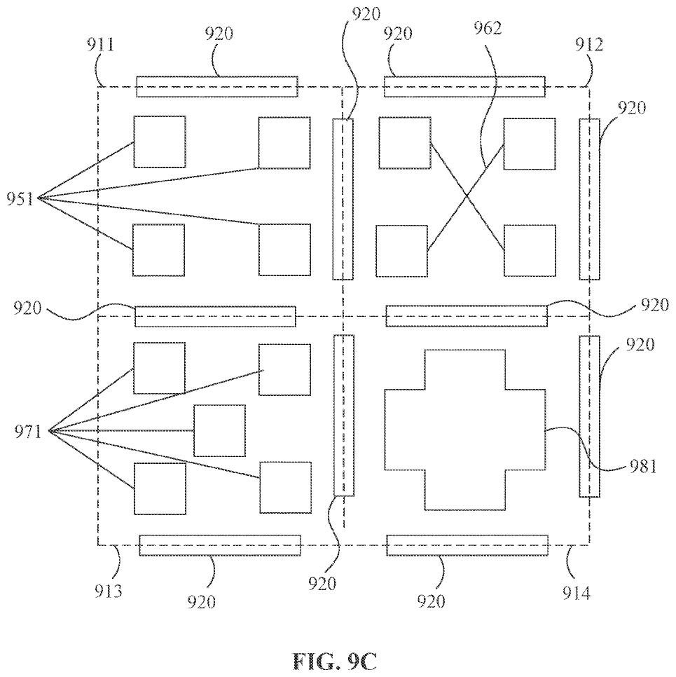

Reference is now made to FIGS. 9A-9C, which illustrate examples of variations of fourth regions, consistent with embodiments of the disclosure. FIG. 9A shows a section of a detector including sensing elements 911, 912, 913, and 914. Each sensing element may include a pickup point 910. Pickup point 910 may be included in fourth regions of the detector. Boundaries of sensing elements may be indicated with dashed lines. The dashed lines may overlap with third regions of a sensing element. For example, as shown in FIG. 9B, region 920 may be provided between adjacent pickup points. Pickup points 910 may be provided between adjacent regions 920. Region 920 may include circuitry, electrical components, signal processing components, switches, and the like. Region 920 may include transistors. Region 920 may correspond with third regions discussed above with reference to FIG. 5 that may include transistors 329.

Properties of a detector, such as geometry, may be configured so that carrier transport behavior is improved while maintaining areas for functional components, such as switches used to connect adjacent sensing elements. A sensing element may include multiple areas of fourth regions. A sensing element may include an array of fourth regions. As shown in FIG. 9A, pickup point 910 may include extension region 930. Extension region 930 may be connected to a main body of pickup point 910 by bridge portion 935. Pickup point 910 may be continuous with bridge portion 935 and extension region 930. Extension region 930 may be provided to increase the occupancy ratio of sensing elements. Various irregular shapes may be used. Extension region 930 may be formed so as to avoid region 920. In some embodiments, multiples of extension region 930 may be provided. For example, pickup point 910 may include four extension regions 930.

Furthermore, various shapes of pickup point 910 may be used. Pickup points 910 may generally have a square shape. Pickup points 910 may deviate from a square shape. Pickup points 910 may include angled corners. Pickup points 910 may be provided as a polygon. Pickup points 910 may be provided as an octagon.

As shown in FIG. 9B, extension region 930 may be connected to the main body of pickup point 910 by a wiring line 936. Wiring line 936 may have a reduced footprint relative to bridge portion 935. Using wiring line 936 may allow area of region 920 to be increased. According to a desired application, size of region 920 may be adapted to allow for placement of desired components.

Additionally, wiring line 936 may have lower capacitance than bridge portion 935. In some embodiments, charged particles may be incident on a detector in random patterns. Pickup points may be configured so as to connect active areas with a short path and with low capacitance. Capacitance of pickup points may be proportional to the area of the pickup points. The greater the area of the pickup point, the higher the capacitance. Higher capacitance may increase the time constant associated with a sensing element. Higher capacitance may have a negative effect on speed. For example, a sensing element with a higher capacitance may have a slower readout speed. In some embodiments, geometry of pickup points may be configured so as to optimize detector performance in view of potential increased capacitance due to enlarged pickup points.

In some embodiments, arrays of pickup points may be used. Arrays of multiple pickup points may be formed on a second side of a substrate of a detector and may be arranged between adjacent third regions that may include electronic components such as transistors. As shown in FIG. 9C, sensing element 911 may include an array 951 of multiple pickup points. Array 951 may be formed between adjacent regions 920.

A detector may include sensing elements with the same or different arrangements of pickup points. For example, as shown in FIG. 9C, sensing element 912 may include an array of pickup points that is connected with wiring lines 962. Sensing element 913 may include an array 971 of a different number of pickup points from that of array 951. Pickup points of an array may be arranged in a manner to cover different regions of a sensing element. For example, an array may be configured to cover the center and corners of a sensing element. Also, in addition to arrays, further variations may include contiguous shapes, such as shape 981 in sensing element 914.

Pickup points in a sensing element may be configured in a manner to balance capacitance with modifications in geometry to improve carrier transport behavior. Properties of pickup points may be configured so that carriers migrate toward the pickup points more effectively. Pickup points may be broadened so that a greater proportion of area on the detector backside is covered by pickup points. A greater proportion of area may be provided by enlarging one or more pickup points, or by providing multiple pickup points (e.g., an array). Multiple arrays of pickup points may be provided in a detector. Carriers may be enabled to travel to pickup points by drift behavior (e.g., using a driver field) rather than by diffusion.

In some embodiments, a driver field may be applied in a direction different from the incidence direction of charged particles on the detector. Charged particles may be incident on the detector in the thickness direction of the detector. In a comparative example, a driver field may be applied in the thickness direction to push carriers generated in the detector to pickup points. In some embodiments of the disclosure, a driver field applied in a different direction may be applied alternatively or in addition to the driver field applied in the thickness direction. Driver field applied in such direction may cause carriers located in regions where carriers may otherwise stagnate to be moved toward pickup points by drift behavior.

Driver electrodes may be arranged adjacent to pickup points. Driver electrodes may be arranged next to pickup points in a direction perpendicular to the thickness direction of the detector. The direction perpendicular to the thickness direction of the detector may be the horizontal direction of the detector. The direction may also be referred to as the lateral direction or the transverse direction of the detector. In some embodiments, a substantially horizontal driver field may be generated between driver electrodes and pickup points, and carriers that may be located in regions between adjacent pickup points may be moved out of such regions and toward pickup points. Horizontal driver field may be applied together with vertical driver field. Carriers may experience drift behavior in both directions, rather than relying only on diffusion to be moved in the horizontal direction.

Regions formed in the second side of the detector may include driver electrodes and pickup points. Pickup points and driver electrodes may be structurally similar. Some pickup points may act as driver electrodes by way of having a different potential applied to them. In some embodiments, some pickup points may have a different potential applied to them so as to provide a horizontal field between pickup points. In addition, distance between adjacent pickup points may be reduced relative to a comparative embodiment. The number of pickup points for a certain area of a detector may be increased so as to shorten the pitch between pickup points.

As discussed above with reference to FIG. 7B, there may be regions 720 where carriers generated in a detector may stagnate. A horizontal driver field may be used to move carriers in such regions. The carriers may be moved toward a pickup point. In some embodiments, alternating pickup points may be connected to alternating voltages, such that any two adjacent pickup points generate a lateral electric field between the two pickup points. Carriers may be pushed by drift behavior toward a pickup point due to the generated electric field.

In some embodiments, a charged particle detector may be provided. The charged particle detector may include an electron detection device. The charged particle detector may include a two-dimensional (2D) pixelated detector array, the 2D array extending in a first direction and a second direction (e.g., x-direction and y-direction). The charged particle detector may be formed in a semiconductor substrate. The charged particle detector may be formed on a wafer. The charged particle detector may be configured to generate a driver field in the first direction or the second direction. The charged particle detector may also be configured to generate a driver field in a third direction. The third direction may coincide with the thickness direction of the detector. The third direction may be, for example, a z-direction in a three-axis coordinate system that includes the x-direction and y-direction.

The charged particle detector may include a sensing element. A plurality of sensing elements may be provided. The plurality of sensing elements may be arranged in a 2D array. The sensing elements may be configured to generate carriers in response to a charged particle arrival event. The sensing elements may be formed as a PIN diode.

As discussed above with reference to FIG. 5, sensing element 314 may be formed of a first region on a first side of the substrate (e.g., the upper side in the view of FIG. 5). The first region may include a semiconductor material of a first conductivity. The first region may include p-type semiconductor, such as region 610, surface layer 601, or p epitaxial region 620. Charged particles may enter sensing element 314 from surface layer 601.

Furthermore, the substrate may include a second side opposite to the first side. For example, as shown in FIG. 5, sensing element 314 may include second side 602. Sensing element 314 may be formed of a second region that is formed on the second side of the substrate. The second region may include a semiconductor material of a second conductivity. The second region may include n-type semiconductor, such as region 630 that may be a low dose n type implant region.

Furthermore, sensing element 314 may be formed of third regions on the second side. One or more circuit components, such as transistor 329, may be formed in the third regions on the second side. The third regions may include semiconductor material of the first type (e.g., p-type semiconductor). For example, as shown in FIG. 5, the third regions may include deep p wells 641.

Furthermore, multiple fourth regions may be formed on the second side. The fourth regions may be formed between adjacent third regions. The fourth regions may include an electrode, pickup point, or substrate tap. For example, as shown in FIG. 5, there may be one fourth region that includes electrode 325.

In some embodiments, a first portion of the fourth regions may be connected to a first potential and a second portion of the fourth regions may be connected to a second potential. The first and second potentials may be different from one another.

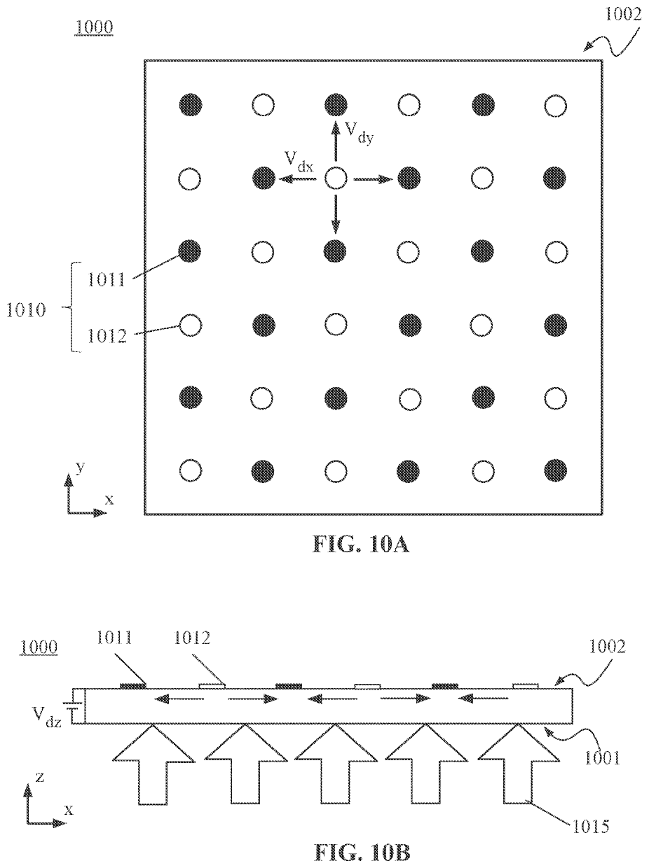

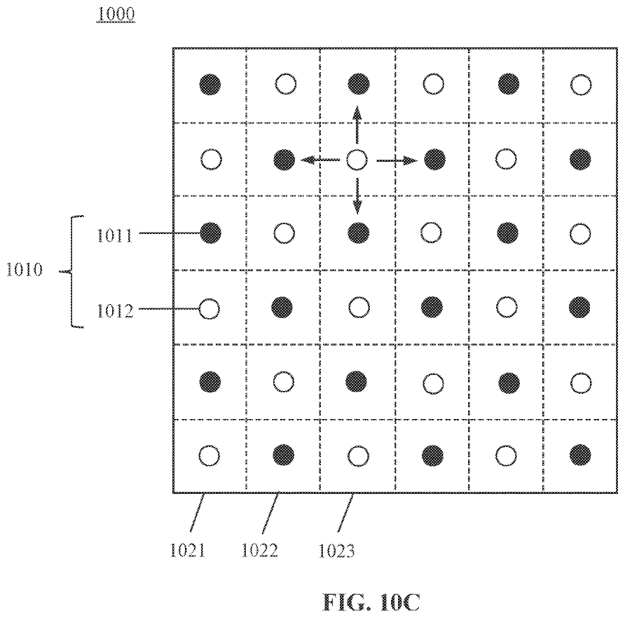

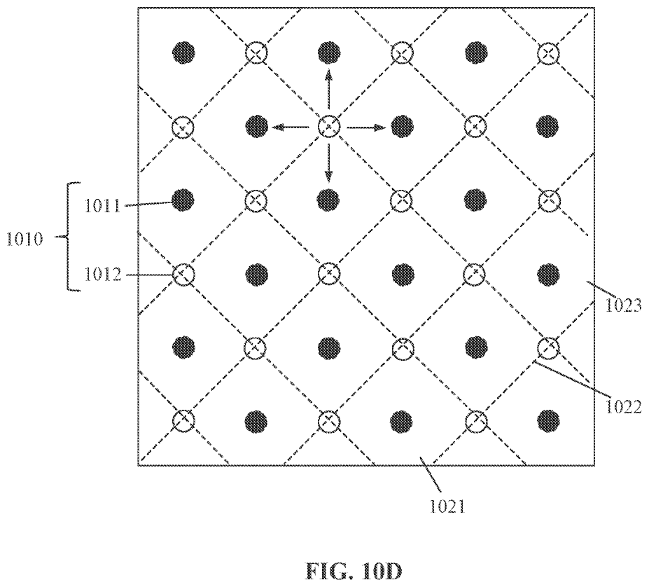

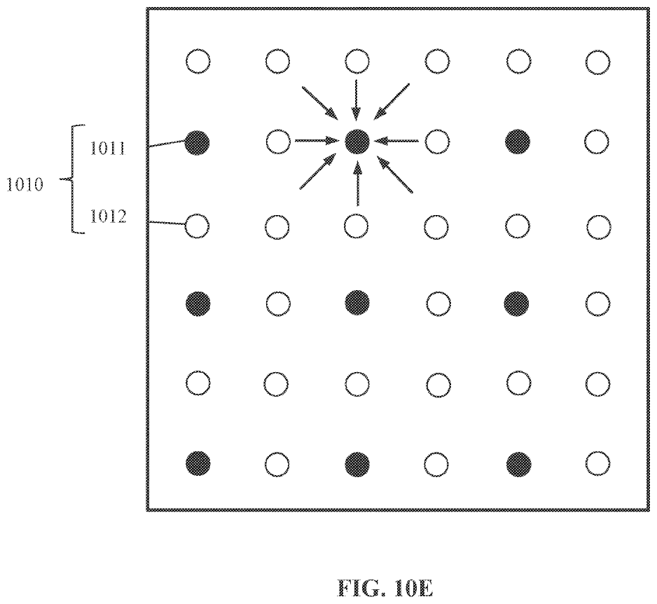

Reference is now made to FIG. 10A and FIG. 10B, which illustrate examples of fourth regions, consistent with embodiments of the disclosure. The fourth regions may include pickup points. The fourth regions may include driver electrodes. Functionality of a pickup point may be determined by a potential applied to the pickup point. FIG. 10A is a plan view of a detector 1000. Detector 1000 may be similar to detector 300, detector 700, or detector 800. FIG. 10B is a side view of detector 1000. Detector 1000 may have a first surface 1001 and a second surface 1002. First surface 1001 may act as a detection surface that is configured to receive charged particles, similar to first surface 301 of detector 300 discussed above with reference to FIG. 3. Circuitry, signal processing components, or other electrical components may be formed on second surface 1002, similar to second surface 302 of detector 300.

As shown in FIG. 10A and FIG. 10B, detector 1000 may include a plurality of fourth regions 1010. Fourth regions 1010 may be formed in second surface 1002. Fourth regions 1010 may include pickup points 1011 and driver electrodes 1012. An arrangement of pickup points 1011 and driver electrodes 1012 may alternate in a checkerboard pattern. Various other patterns may be used.

As shown in FIG. 10B, in operation, driving voltage V_{dz} may be applied to detector 1000. First surface 1001 may include a conductive layer that may act as an anode. First surface 1001 may include or be included in surface layer 601, discussed above with reference to FIG. 5. One or more of fourth regions 1010 may act as cathodes. For example, pickup points 1011 may act as cathodes. Driving voltage V_{dz} may be applied between first surface 1001 and one or more of fourth regions 1010. Driving voltage V_{dz} may be applied to pickup points 1011. Driving voltage V_{dz} may cause a substantially vertical driving field to be generated in detector 1000 that runs from first surface 1001 to second surface 1002 (e.g., in the z-direction). Furthermore, another driving field may be generated in a direction different from that of the substantially vertical driving field (e.g., different from the z-direction). For example, lateral driving voltages V_{dx} and V_{dy} may be applied between driver electrodes 1012 and pickup points 1011. A first voltage may be applied to pickup points 1011 and a second voltage may be applied to driver electrodes 1012. The first and second voltages may be different from one another. Due to differences in applied voltages, electric fields may be generated between pickup points 1011 and driver electrodes 1012. Driving fields may be generated in substantially horizontal directions (e.g., x-direction or y-direction). Driver fields may influence carriers generated in detector 1000 to move the carriers toward pickup points 1011. Detector 1000 may be configured to receive charged particles 1015 on first surface 1001, generate carriers in response to receiving charged particles 1015, and output signals via pickup points 1011. Potentials may be set appropriately among first surface 1001, driver electrodes 1012, and pickup points 1011.

Driver fields may be configured to guide carriers to particular locations. Driver fields may be configured to guide carriers toward pickup points. Voltages between different points in a detector may be set appropriately. Voltages and polarities may be adjusted so as to collect a particular type of carrier. For example, a voltage may be set to attract electrons to pickup points and to attract holes to driver electrodes and other regions (e.g., a surface layer of the detector that may act as a common anode). In some embodiments, driving field may be applied so as to repel carriers from driver electrodes. For example, a driving field may have a magnitude such that carriers are not able to overcome a repelling force and no carriers reach driver electrodes. In some embodiments, driver electrodes may still be able to receive some carriers. A detector may be configured so that carriers are collected through both pickup points and driver electrodes. The detector may include signal processing components configured to process outputs from pickup points and driver electrodes in parallel. For example, parallel processing paths may be provided. Electrons collected through driver electrodes may be processed and added to a signal representing electrons collected through pickup points.

Furthermore, in some embodiments, certain carriers may be guided to pickup points while certain carriers may be guided to driver electrodes or other locations. For example, in response to a secondary electron arrival event in a PIN diode, numerous electron-hole pairs may be generated. Electrons may be guided toward pickup points and holes may be guided toward other locations. For example, holes may be guided toward driver electrodes or surface layer 601. Potentials applied to electrodes may be manipulated depending on the type of carrier to be received.

In some embodiments, a detector may be configured so that each sensing element of the detector includes either a pickup point or a driver electrode. Both pickup points and driver electrodes may be configured to receive carriers. Both pickup points and driver electrodes may receive electrons, and output signal may be determined based on electrons collected from both the pickup points and driver electrodes.

Reference is now made to FIG. 10C, which illustrates another view of detector 1000, consistent with embodiments of the disclosure. In the view of FIG. 10C, individual sensing elements may be indicated with dashed lines. Detector 1000 may include sensing elements 1021, 1022, and 1023.

In some embodiments, arrangements of sensing elements may be modified. A detector may be configured so that each sensing element includes a pickup point. Furthermore, driver electrodes may be arranged at the corner of each sensing element. For example, as shown in FIG. 10D, sensing elements 1021, 1022, and 1023 may have one pickup point 1011 located at a center thereof, and may be surrounded by driver electrodes 1012 at their corners. The detector may be configured so that carriers in each sensing element are guided toward a respective pickup point 1011.

Divisions of sensing elements may be arbitrary. The dashed lines indicating boundaries between sensing elements may not correspond to any physical division. A detector may be configurable such that various arrangements or patterns of pixelated sensing elements may be provided. In some embodiments, boundaries between sensing elements may correspond to locations where electrical components may be arranged. For example, switches configured to connect adjacent sensing elements may be provided at the boundaries between sensing elements. The switches may include transistors.

In some embodiments, dimensions between pickup points or driver electrodes may be manipulated. A distance between pickup points may be decreased so that the length that carriers need to travel to reach a pickup point is reduced. For diffusion behavior, carrier travel time may be proportional to distance squared. Thus, reducing distance (e.g., L) between pickup points may result in a decrease of time needed for carrier diffusion proportional to the square of the distance (e.g., L²). With decreasing pitch between pickup points, the number of pickup points for a certain detector area may be increased.

Reference is now made to FIG. 10E, which illustrates another variation of detector 1000, consistent with embodiments of the disclosure. Detector 1000 may be configured so that each pickup point 1011 is surrounded by driver electrodes 1012. Detector 1000 may be configured to have a pattern of stripes of driver electrodes. Each pickup point 1011 may be enclosed by driver electrodes 1012, and a driver field may be generated that guides substantially all carriers in a certain area toward pickup point 1011.

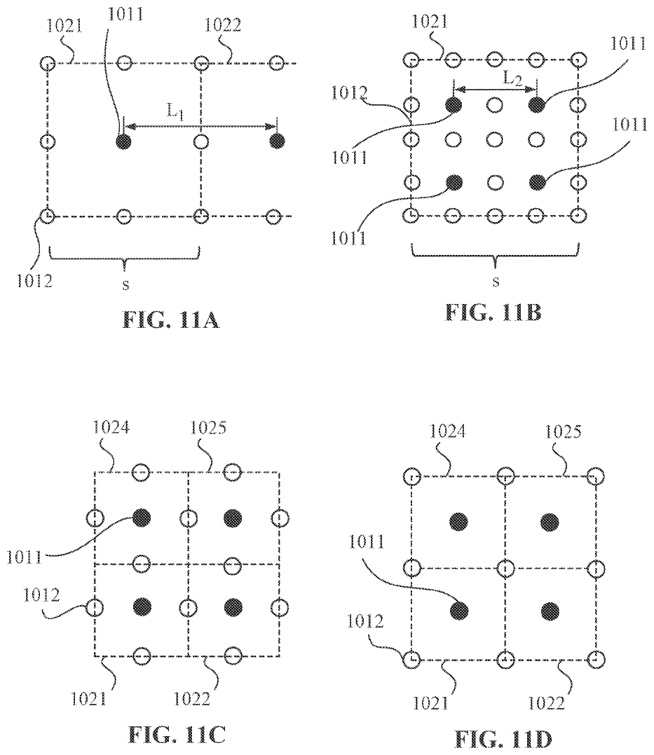

Reference is now made to FIGS. 11A-11D, which illustrate further variations of patterns of fourth regions in a detector, consistent with embodiments of the disclosure. Arrangements of pickup points and driver electrodes may be manipulated. Spacing of pickup points and driver electrodes may be manipulated.

As shown in FIG. 11A, sensing element 1021 may include pickup point 1011. Pickup point 1011 may be surrounded by driver electrodes 1012. FIG. 11A may represent a pattern similar to that of FIG. 10E. The pattern shown in FIG. 11A may be regularly repeating over the second surface of a detector. For example, adjacent sensing element 1022 may have a similar pattern (partially shown in FIG. 11A). A distance between adjacent pickup points may be set to L₁. L₁ may be equal to a dimension s of sensing element 1021. Spacing of pickup points may be the same as the length of sensing elements in a detector. Spacing of pickup points may include the pitch of pickup points. In some embodiments, patterns may be irregular. For example, driver electrodes 1012 may be arranged at locations different from the midpoint between adjacent pickup points 1011. Distance between adjacent pickup points may be non-uniform (e.g., distance between a first group of pickup points may be set to L₁ while distance between a second group of pickup points may be set to be different from L₁).

In some embodiments, spacing of pickup points may be reduced. Pickup points may be made closer together. Paths that carriers take to reach pickup points in a sensing element of a detector may be reduced. The number of pickup points in the detector may be increased overall. Driver electrodes may be similarly modified.

As shown in FIG. 11B, sensing element 1021 may have a greater number of pickup points 1011 and driver electrodes 1012 than that of FIG. 11A. A distance between adjacent pickup points may be set to L₂. L₂ may be less than L₁. In some embodiments. L₂ may be less than or equal to one half of L₁. A sensing element may include multiple pickup points. As shown in FIG. 11B, sensing element 1021 may include four pickup points 1011. A greater number of pickup points may shorten the path that carriers generated within the sensing element are required to take to reach a pickup point. In both FIG. 11A and FIG. 11B, dimension s of sensing element 1021 may be equal. Thus, for the same sensing element area, a number of pickup points or driver electrodes may be adjusted, and spacing of the pickup points or driver electrodes may be adjusted. For a predetermined area of a sensing element, a number of pickup points or driver electrodes may be adjusted. A sensing element may be configured to have a plurality of pickup points. A sensing element may be configured to have a plurality of driver electrodes arranged around its perimeter. In some embodiments, driver electrodes may be provided within an inner area of a sensing element.

FIG. 11C shows a further variation of patterns that may be used for pickup points and driver electrodes. Driver electrodes 1012 may be provided between adjacent pickup points 1011. As shown in FIG. 11C, pickup points and driver electrodes need not necessarily be provided uniformly. Locations of driver electrodes may be provided in certain areas so as to avoid regions occupied by other components. For example, although FIG. 11C shows driver electrodes 1012 between adjacent pickup points 1011, locations of driver electrodes 1012 may be shifted laterally to accommodate electronics that may be provided between pickup points 1011.

FIG. 11D shows a further variation of patterns that may be used for pickup points and driver electrodes. Driver electrodes 1012 may be formed at the corners of sensing elements. Driver electrodes 1012 may be between adjacent sensing elements in a diagonal direction of the detector.

In some embodiments, pickup points and driver electrodes may be formed with different structures. Pickup points and driver electrodes may be formed with the same material but with other different parameters, such as size or shape. Furthermore, a number of driver electrodes and a number of pickup points in a detector may be different.

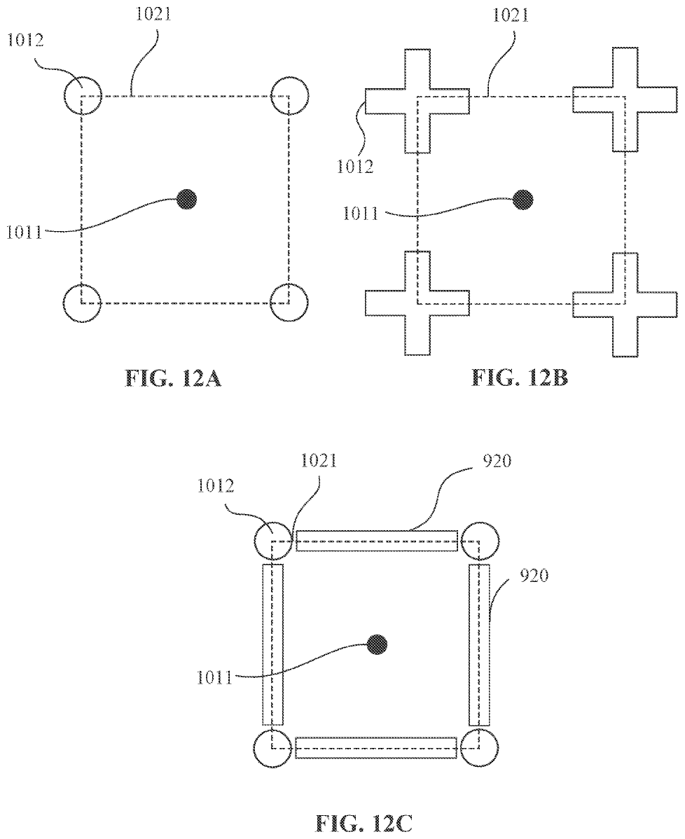

Reference is now made to FIG. 12A and FIG. 12B, which illustrate further variations of patterns that may be used for pickup points and driver electrodes, consistent with embodiments of the disclosure. Pickup points and driver electrodes may be provided nonuniformly. As shown in FIG. 12A, a size of driver electrodes 1012 may be larger than that of pickup point 1011. Size of pickup points may be minimized so as to reduce capacitance, whereas, size of driver electrodes may be increased so as to increase the ability of the driver electrodes to guide carriers away from driver electrodes and toward pickup points. In some embodiments, driver electrodes may be configured not to receive carriers of interest (e.g., electrons), and the size and corresponding capacitance of driver electrodes may be deprioritized. In some embodiments, capacitance of driver electrodes may be increased without having a negative impact on detector performance (e.g., speed). In some embodiments, driver electrodes may be configured to receive carriers of non-interest (e.g., holes).

Furthermore, in some embodiments, parameters of driver electrodes themselves may be modified. Driver electrodes may be configured to have irregular shapes. Driver electrodes may be configured to have shapes so as to fill out regions that are not occupied by other components. For example, as shown in FIG. 12B, driver electrodes 1012 may be provided with a cross shape. Between adjacent driver electrodes 1012, sensing element 1021 may include electronic components, such as transistors. Driver electrodes 1012 may be sized so as to fill out peripheral regions of sensing element 1021 that are otherwise unused. Meanwhile, size of pickup point 1011 may be minimized so as to reduce capacitance. In some embodiments, in addition or alternative to increasing size or modifying a shape of driver electrodes, a higher potential may be applied to driver electrodes to generate a stronger driving field in horizontal directions.

As shown in FIG. 12C, fourth regions may be arranged between third regions. Fourth regions may include a first portion that may include pickup points and a second portion that may include driver electrodes. Third regions may include circuit components, such as transistors. A detector may be configured so that a peripheral area of a sensing element is substantially filled with either third or fourth regions. In some embodiments, each sensing element may have a pickup point located at its center. For example, as shown in FIG. 12C, pickup point 1011 may be located at the center of sensing element 1021. Each of driver electrodes 1012 may be between adjacent regions 920 that may include electrical components, such as transistors.

In some embodiments, a source of radiation may be used to bias a detector. The source may be provided in addition to a primary source that is configured to cause secondary charged particles to be emitted onto the detector. A first source may be provided that is configured to generate a primary charged particle beam. And a second source may be provided that is configured to bias the detector. The second source may generate a supply of free carriers in the detector. The detector may be saturated with free carriers such that when a secondary charged particle arrival event occurs, a response may be detected at pickup points of the detector faster than a case in which no biasing is used. Detection of output may involve performing signal processing that accounts for the extra free carriers generated by the second source.

A substrate of a detector may be irradiated by a source. The substrate may be sensitive to radiation provided by the source such that free carriers may be generated in the substrate in response to being irradiated by the source. The source may include a laser, LED, charged particle beam, or any other source of radiation. In some embodiments, a PIN diode may be irradiated by a laser, LED, or electron beam to generate a constant supply of electron-hole pairs. Electrons may be swept by an electric field (e.g., a driver field) to pickup points of the PIN diode. The supply of free electron-hole pairs may increase horizontal conductivity in the PIN diode and may increase detector speed. The time span from arrival of an incident secondary electron at the PIN diode, where the secondary electron may generate numerous carriers (e.g., electrons) in the depletion region of the PIN diode, to the collection of carriers (e.g., electrons) at the pickup points may be reduced.

In some embodiments, an impulse of carriers may be delivered to a pickup point in response to a secondary electron arrival event. A change in a rate of carrier collection may be detected. In some embodiments, a change in potential may be detected at the pickup point.

An external source may be configured to illuminate a detector so as to increase a conductivity of active areas of the detector. Conductivity may be proportional to free charge concentration. A copper material may have a higher electron concentration than a glass material and the copper material may be more conductive than the glass material. Similarly, a biased detector may have greater conductivity than an unbiased detector. Analogizing to a vessel filled with fluid, overflow of the vessel will occur more quickly when the vessel is filled rather than when the vessel is empty. In some embodiments of the disclosure, a detector may be biased so that an increased amount of free carriers are present in sensing elements of the detector, and the detector's response to charged particle arrival events by outputting signals at pickup points is made faster.

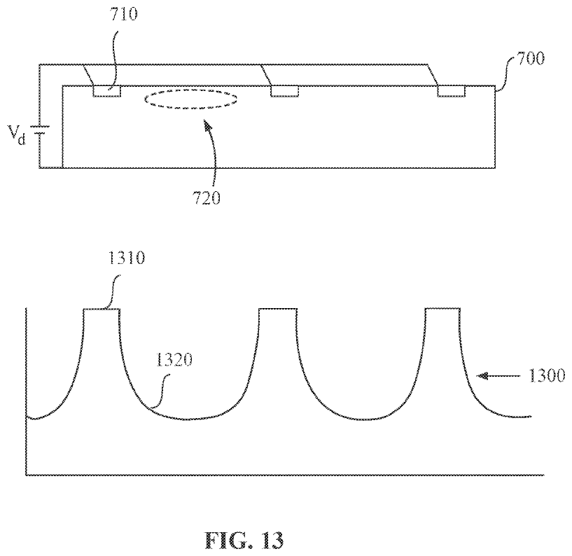

Reference is now made to FIG. 13, which is a diagrammatic representation of attraction of carriers to pickup points, consistent with embodiments of the disclosure. As discussed above with reference to FIG. 7A and FIG. 7B, carriers may be driven by a substantially vertical field toward pickup points 710. There may be regions 720 where carriers may stagnate, and carriers may move primarily by diffusion behavior. As shown in FIG. 13, a graph 1300 may represent static potential of carriers in relation to location in detector 700. The abscissa of graph 1300 may correspond to a lateral position in detector 700. The ordinate of graph 1300 may represent static potential (e.g., level of attraction to pickup points). There may be regions 1310 where carriers are highly attracted to pickup points 710. Meanwhile, there may be regions 1320 where static potential is relatively low, and carriers may not be strongly attracted to pickup points 710.

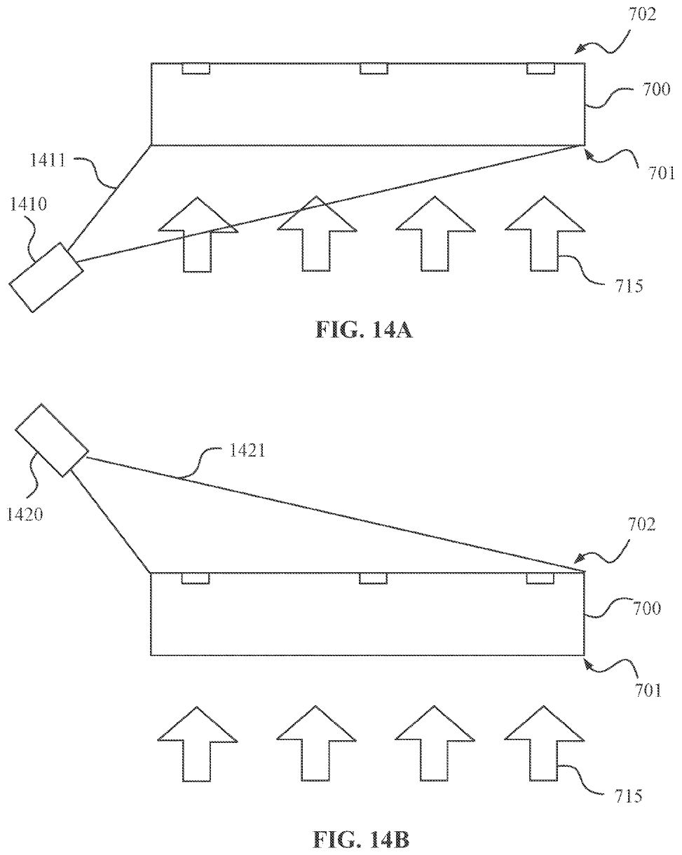

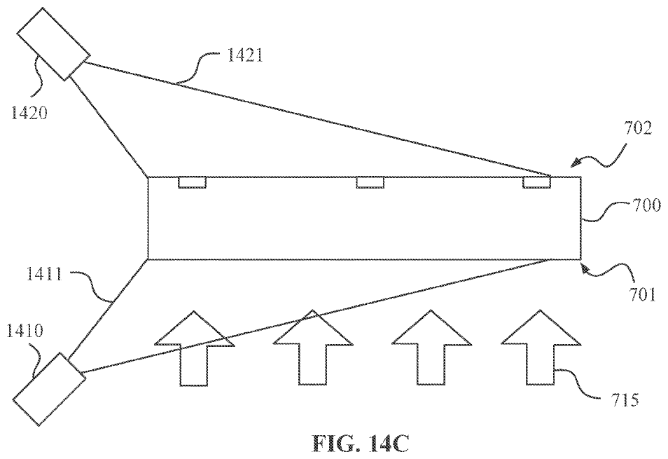

In some embodiments, illumination may be provided by an external source to generate a supply of carriers in a detector. FIGS. 14A-14C illustrate examples of illumination provided by external sources, consistent with embodiments of the disclosure.

As shown in FIG. 14A, there may be provided a first external source 1410. First external source 1410 may be configured to generate radiation that is incident on detector 700. First external source 1410 may be configured to irradiate first surface 701 of detector 700. While being irradiated by first external source 1410, charged particles 715 may be received on detector 700 via first surface 701.

In some embodiments, illumination may be provided on a first side or a second side of a detector. As shown in FIG. 14B, there may be provided a second external source 1420. Second external source may be configured to generate radiation that is incident on detector 700. Second external source 1420 may be configured to irradiate second surface 702 of detector 700. While being irradiated by first external source 1410, charged particles 715 may be received on detector 700 via first surface 701.

In some embodiments, as shown in FIG. 14C, both first external source 1410 and second external source 1420 may be provided. First external source 1410 may be configured to irradiate first surface 701 of detector 700 and second external source 1420 may be configured to irradiate second surface 702 of detector 700. While being irradiated by both first external source 1410 and second external source 1420, charged particles 715 may be received on detector 700 via first surface 701.

First external source 1410 or second external source may include a laser, LED, charged particle beam source, or any other radiation source. In some embodiments, a source configured to irradiate second surface 702 of detector 700 may be configured to emit a type of radiation that does not damage electronics that may be provided on second surface 702. In some embodiments, a mask may be provided to shield sensitive areas of second surface 702. In some embodiments, second external source 1420 may be configured to emit radiation selectively.

Second external source 1420 may be configured to inject radiation to certain areas on second surface 702 of detector 700. Second external source 1420 may be configured to generate free carriers in regions of detector 700 where the effects of increased carrier concentration may be most pronounced.

Second external source 1420 may be configured to illuminate an area between a pickup point in a sensing element and the edge of the sensing element. The area may include a region between the pickup point and a transistor or other electronics arranged between adjacent sensing elements. Second external source 1420 may be configured to illuminate region 720. In some embodiments, second external source 1420 may include a light guide and may be configured to illuminate a portion of second surface 702 directly above region 720.

First external source 1410 may be configured to generate radiation that penetrates first surface 701 of detector 700. In some embodiments, first external source 1410 may include a charged particle flood gun. First surface 701 of detector 700 may be flooded over a broad region with dispersed charged particles. The charged particles may generate carriers in detector 700 without damaging electronic components of detector 700.

Detecting carriers via pickup points 710 may include performing signal analysis. External illumination of detector 700 may cause an increase in the number of free carriers generated in detector 700. Output signal of a sensing element may be formed by carriers that are collected at pickup point 710 for the particular sensing element. To obtain a signal representing only a charged particle arrival event, a portion of signal corresponding to the free carriers may be subtracted from a total signal. For example, an external source may be configured to generate a first number of carriers in a sensing element. The first number of carriers may be determined from experimentation or simulation. The first number of carriers may be determined based on an amount of energy provided by the external source and properties of detector 700. In response to a charged particle arrival event at the sensing element, a second number of carriers may be generated in the sensing element. Meanwhile, a third number of carriers may be collected at the pickup point of the sensing element. The second number of carriers may be obtained by subtracting the first number of carriers from the third number of carriers. The second number of carriers may be representative of the charged particle arrival event. The third number of carriers may include a total number of carriers collected at the pickup point. The third number of carriers may include the first number of carriers and the second number of carriers.

In some embodiments of the disclosure, a method of detecting charged particles may be provided. The method may be performed using a charged particle beam system.

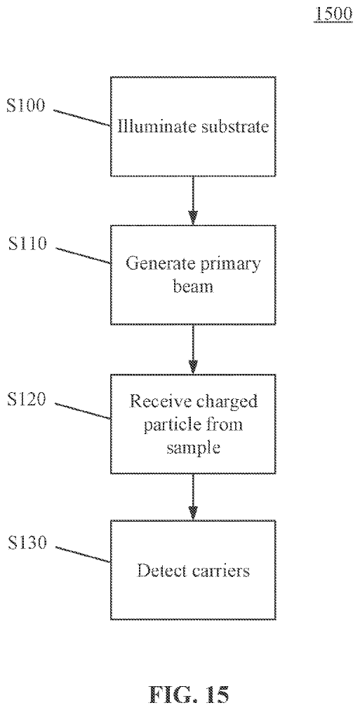

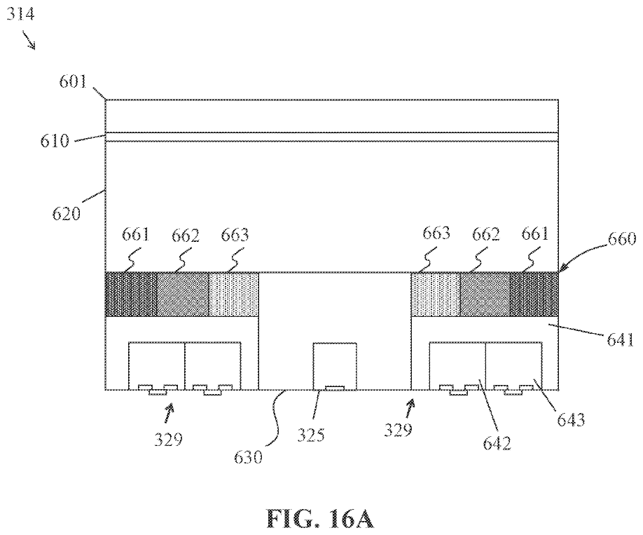

Reference is now made to FIG. 15, which is a flowchart illustrating a method 1500 that may be useful for charged particle detection, consistent with embodiments of the disclosure. Method 1500 may be performed by a controller of the charged particle beam system (e.g., controller 109 in FIG. 1 or FIG. 2B. In some embodiments, the controller may be included in detector 144 or electron detection device 244. The controller may include circuitry (e.g., a memory and a processor) programmed to implement method 1500. The controller may be an internal controller or an external controller coupled with the charged particle beam system.

As shown in FIG. 15, method 1500 may begin at a step S100. Step S100 may include illuminating a substrate. Illumination may be performed continuously for a period. Illumination may be performed continuously during a period wherein SEM imaging is conducted. Illumination may be performed continuously as scanning of a sample is performed. Illumination may be performed continuously during a scan of a sample. The substrate may include a portion of a detector. Illuminating the substrate may cause generation of carriers in the substrate. The substrate may include a PIN diode of the detector. The illumination may cause a flow of electron-hole pairs to be generated in a depletion region of the PIN diode. Flow of carriers may be related to the illumination projected on the substrate. Flow of carriers may have a relation, such as proportionality, to the illumination. For example, amount of carriers generated may be proportional to intensity of the illumination. As the illumination is projected onto the substrate, a constant flow of carriers may be generated. The illumination may be generated by an external source that may include a laser, LED, electron beam source, or other radiation source.

Method 1500 may include a step S110 of generating a primary charged particle beam. The primary charged particle beam may be generated by electron beam tool 100. Generating the primary charged particle beam may include generating a plurality of beamlets. Generation of the primary charged particle beam may cause secondary beam(s) to be formed that are directed to the detector of the charged particle beam system. The primary charged particle beam may be scanned over a surface of a sample.

Method 1500 may include a step S120 of receiving, at the substrate, a charged particle emitted from the sample. The charged particle may be directed to the substrate from the sample having been scanned by the primary charged particle beam of the charged particle beam system. The charged particle may include a secondary electron. The charged particle may be incident on a first side of the substrate. The charged particle may interact with the depletion region of the PIN diode that may form the substrate and may trigger generation of numerous carriers in the PIN diode. The charged particle may generate numerous electron-hole pairs. Numerosity of carriers may be related to properties of the incoming charged particles on the substrate, and properties of the substrate. For example, in some embodiments, a PIN diode may be configured such that kinetic energy of an incoming electron having energy (BE−LE) keV may be fully consumed by creating numerous electron-hole pairs at a rate of about 3.61 eV per pair. Therefore, for an incoming electron of 10,000 eV energy, approximately 2,700 electron-hole pairs may be created. In contrast to a photon arrival event that may generate just a single electron-hole pair, electron arrival events may generate significantly more electron-hole pairs.

Method 1500 may include a step S130 of detecting carriers via a pickup point on the substrate. The pickup point may be provided on a second side of the substrate. The second side may be opposite to the first side. The illumination of the substrate may cause an increased concentration of carriers in a region of the substrate. The concentration of carriers in the region of the substrate may be increased relative to an unilluminated state. The region may include semiconductor material of a certain type.

The substrate may include a first region formed of semiconductor material of a first conductivity, and a second region formed of semiconductor material of a second conductivity. The first region may be provided on the first side of the substrate. The second region may be provided on the second side of the substrate. The first region may include p type semiconductor. The second region may include n type semiconductor. For example, as shown in FIG. 5, there may be a first region that includes surface layer 601, region 610, or p epitaxial region 620. There may also be a second region that includes 630. Region 630 may be a low dose n type implant region.

A substrate that includes a portion of a charged particle detector may include sensing element 314. The substrate may be illuminated via surface layer 601 or second side 602. Illumination of sensing element 314 may cause an increased concentration of carriers in region 630. Increased concentration of carriers in region 630 may facilitate conduction of carriers toward electrode 329.

In some embodiments, a differential gradient may be provided in sensing elements. The differential gradient may be configured to generate a field to influence carriers. The differential gradient may be configured to facilitate conduction of carriers toward pickup points. The differential gradient may generate a passive field. The differential gradient may be formed in a particular direction. The differential gradient may have a gradient in the horizontal direction between pickup points. A sensing element may be constructed from a semiconductor substrate. A gradient of implants, such as stepped implant regions, may be used. The differential gradient may cause carriers in a region between pickup points to move toward the closest pickup point.

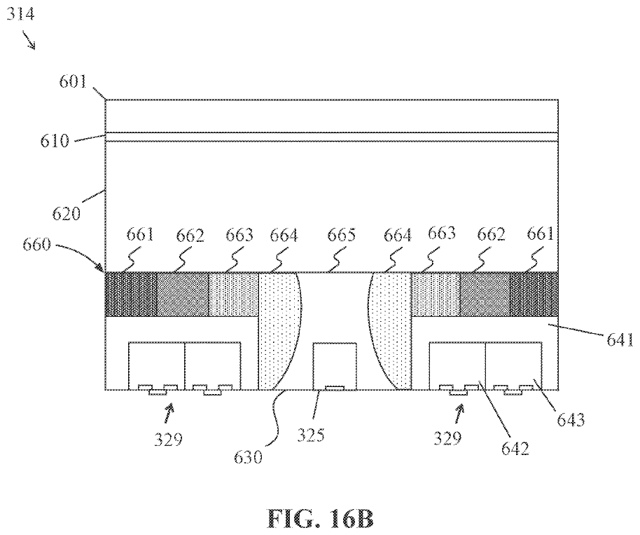

Reference is now made to FIG. 16A and FIG. 16B, which illustrate differential gradients, consistent with embodiments of the disclosure. As shown in FIG. 16A, sensing element 314 may be provided that is similar to that of FIG. 5, except that region 630 may include a gradient region 660. Gradient region 660 may include a differential gradient. Gradient region 660 may include a plurality of regions having different conductivity.

In FIG. 5, sensing element 314 may include region 630 that may be a uniform structure. Region 630 may be a low dose n type implant region. However, in FIG. 16A, sensing element 314 may include region 630 with regions of differing conductivity. Region 630 may include gradient region 660. Gradient region 660 may be formed with regions having different dosages of n type implants. For example, a first gradient region 661, second gradient region 662, and third gradient region 663 may be provided. Regions 661, 662, 663 may have different doping densities. First gradient region 661 may have a higher doping density than second gradient region 662, which may have a higher doping density than third gradient region 663. For example, first gradient region 661 may be an n++ region, second gradient region 662 may be an n+ region, and third gradient region 663 may be an n region. Different doping densities of the different regions may cause carriers to move in a predetermined direction. The gradient of gradient region 660 may be formed in the predetermined direction. The predetermined direction may be the horizontal direction of the detector.

A detector may be formed with gradient regions using various manufacturing processes. Different semiconductor regions may be formed using different masks, or by implanting different densities of dopants.

In some embodiments, a gradient region may be provided at particular locations in a detector. For example, as discussed above with reference to FIG. 7B, there may be regions 720 where carriers may tend to stagnate. Gradient regions may be formed in such areas.

As shown in FIG. 16A, gradient region 660 may be formed to overlap with transistor 329 in the thickness direction of the detector. Gradient region 660 may be formed between transistor 329 and region 620. Gradient region 660 may be formed selectively in areas where carrier transport behavior is desired to be manipulated. When a vertical driver field is applied, carrier transport may be sufficient in regions except for regions 720. In some embodiments, a vertical driver field may be used with gradient regions 660 formed in an area corresponding to regions 720.

In some embodiments, further manipulation of carrier transport behavior may be desired. Gradient regions may be formed in areas extending beyond regions 720. In some embodiments, gradient regions may fill an entire area of a second region of a substrate of a detector.

The substrate of the detector may include a first region formed of semiconductor material of a first conductivity, and a second region formed of semiconductor material of a second conductivity. The first region may be provided on the first side of the substrate. The second region may be provided on the second side of the substrate. The first region may include p type semiconductor. The second region may include n type semiconductor. For example, as shown in FIG. 5, there may be a first region that includes surface layer 601, region 610, or p epitaxial region 620. There may also be a second region that includes 630. Region 630 may be a low dose n type implant region.

As shown in FIG. 16B, gradient region 660 may be formed to fill substantially all of region 630. Similar to FIG. 16A, gradient region 660 may include first gradient region 661, second gradient region 662, and third gradient region 663. In addition, gradient region 660 may include fourth gradient region 664 and fifth gradient region 665. Gradient region 660 may be configured to form a smooth transition of dopant density from first gradient region 661 to fifth gradient region 665.

A non-transitory computer-readable medium may be provided that stores instructions for a processor of a controller (e.g., controller 109 in FIG. 1) for detecting charged particles according to the exemplary flowchart of FIG. 15, consistent with embodiments of the present disclosure. For example, the instructions stored in the non-transitory computer-readable medium may be executed by the circuitry of the controller for performing method 1500 in part or in entirety. Common forms of non-transitory media include, for example, a floppy disk, a flexible disk, hard disk, solid-state drive, magnetic tape, or any other magnetic data storage medium, a Compact Disc Read-Only Memory (CD-ROM), any other optical data storage medium, any physical medium with patterns of holes, a Random Access Memory (RAM), a Programmable Read-Only Memory (PROM), and Erasable Programmable Read-Only Memory (EPROM), a FLASH-EPROM or any other flash memory, Non-Volatile Random Access Memory (NVRAM), a cache, a register, any other memory chip or cartridge, and networked versions of the same.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

The embodiments may further be described using the following clauses:

1. A charged particle detector comprising:
a plurality of sensing elements formed in a substrate, wherein a sensing element of the plurality of sensing elements is formed of a first region on a first side of the substrate, and a second region on a second side of the substrate, the second side being opposite to the first side;
a plurality of third regions formed on the second side of the substrate, the third regions including one or more circuit components; and
an array of fourth regions formed on the second side of the substrate, the array of fourth regions being between adjacent third regions.

2. The charged particle detector of clause 1, wherein
the first region includes semiconductor material of a first conductivity,
the second region includes semiconductor material of a second conductivity,
the third region includes semiconductor material of the first conductivity, and
the array of fourth regions includes semiconductor material of the second conductivity.

3. The charged particle detector of clause 1 or clause 2, wherein
the first region includes p type semiconductor,
the second region includes n type semiconductor,
the third region includes p type semiconductor, and
the fourth region includes n type semiconductor.

4. The charged particle detector of any one of clauses 1-3, wherein the second region is adjacent to the first region.

5. The charged particle detector of any one of clauses 1-4, wherein the sensing element includes a PIN diode.

6. The charged particle detector of any one of clauses 1-5, wherein the array of fourth regions is connected by a wiring path.

7. The charged particle detector of any one of clauses 1-5, wherein the array of fourth regions is connected by a bridge portion.

8. The charged particle detector of any one of clauses 1-7, wherein the array of fourth regions includes electrodes configured to collect carriers generated in the sensing element.

9. The charged particle detector of any one of clauses 1-8, wherein the one or more circuit components include transistors.

10. A charged particle detector comprising:
a plurality of sensing elements formed in a substrate, wherein a sensing element of the plurality of sensing elements is formed of a first region on a first side of the substrate, and a second region on a second side of the substrate, the second side being opposite to the first side;
a plurality of third regions formed on the second side of the substrate, the third regions including one or more circuit components; and
a fourth region formed on the second side of the substrate, the fourth region being between adjacent third regions, a parameter of the fourth region being configured so as to enhance carrier transport in the detector.

11. The charged particle detector of clause 10, wherein the parameter of the fourth region includes geometry of the fourth region.

12. The charged particle detector of clause 10 or clause 11, wherein an occupancy ratio of the fourth region in the sensing element is greater than or equal to a predetermined proportion.

13. The charged particle detector of clause 12, wherein the predetermined proportion is 50%.

14. The charged particle detector of any one of clauses 10-13, wherein the fourth region includes a contiguous shape.

15. A charged particle detector comprising:
a plurality of sensing elements formed in a substrate, wherein a sensing element of the plurality of sensing elements is formed of a first region on a first side of the substrate, and a second region on a second side of the substrate, the second side being opposite to the first side;
a plurality of third regions formed on the second side of the substrate, the third regions including one or more circuit components; and
a plurality of fourth regions formed on the second side of the substrate, a first portion of the plurality of fourth regions being connected to a first potential and a second portion of the plurality of fourth regions being connected to a second potential different from the first potential.

16. The charged particle detector of clause 15, wherein a third potential is applied to the first region.

17. The charged particle detector of clause 15 or clause 16, wherein a field is formed between the first portion of the plurality of fourth regions and the second portion of the plurality of fourth regions in substantially a lateral direction of the charged particle detector, the lateral direction being perpendicular to a thickness direction of the charged particle detector and an incidence direction of charged particles on the charged particle detector.

18. The charged particle detector of any one of clauses 15-17, wherein a structure of each of the first portion of the plurality of fourth regions is the same as that of each of the second portion of the plurality of fourth regions.

19. The charged particle detector of any one of clauses 15-17, wherein a structure of each of the first portion of the plurality of fourth regions is different from that of each of the second portion of the plurality of fourth regions.

20. The charged particle detector of clause 19, wherein a size of the second portion of the plurality of fourth regions is greater than that of the first portion of the plurality of fourth regions.

21. The charged particle detector of any one of clauses 15-20, wherein a number of the second portion of the plurality of fourth regions is greater than that of the first portion of the plurality of fourth regions.

22. The charged particle detector of any one of clauses 15-21, wherein each of the plurality of sensing elements includes one of the first portion of the plurality of fourth regions.

23. The charged particle detector of any one of clauses 15-21, wherein the plurality of fourth regions are provided in a checkerboard pattern.

24. The charged particle detector of clause 23, wherein the first portion of the plurality of fourth regions and the second portion of the plurality of fourth regions are provided alternately.

25. The charged particle detector of any one of clauses 15-21, wherein the plurality of fourth regions are provided in a pattern such that each of the first portion of fourth regions is surrounded by the second portion of fourth regions.

26. The charged particle detector of any one of clauses 15-25, wherein the first portion of the plurality of fourth regions includes electrodes configured to collect a first type of carrier generated in the sensing element and the second portion of the plurality of fourth regions includes driver electrodes configured to repel the first type of carrier.

27. The charged particle detector of any one of clauses 15-25, wherein the first portion of the plurality of fourth regions and the second portion of the plurality of regions include electrodes configured to collect a first type of carrier generated in the sensing element.

28. The charged particle detector of clause 27, further comprising a circuit configured to perform signal processing to generate an output based on the first type of carrier collected by both the first portion of the plurality of fourth regions and the second portion of the plurality of regions.

29. The charged particle detector of any one of clauses 15-28, wherein each of the first portion of the plurality of fourth regions is located at the center of a sensing element and each of the second portion of the plurality of fourth regions is between adjacent third regions.

30. A method for detecting charged particles comprising:
illuminating a substrate that includes a portion of a detector to cause generation of a stream of carriers in the substrate;
receiving, at the substrate, a charged particle emitted from a sample, wherein the charged particle interacts with the substrate to trigger generation of numerous carriers in the substrate; and
detecting carriers via a pickup point on the substrate.

31. The method of clause 30, wherein the substrate includes a PIN diode and illuminating the substrate causes generation of a constant stream of electron hole pairs in a depletion region of the PIN diode.

32. The method of clause 30 or clause 31, wherein the substrate is illuminated continuously during a period.

33. The method of any one of clauses 30-32, wherein the substrate is illuminated on a first side that is configured to receive incident charged particles from the sample.

34. The method of any one of clauses 30-32, wherein the substrate is illuminated on a second side, the second side being opposite to a first side that is configured to receive incident charged particles from the sample.

35. The method of any one of clauses 30-32, wherein the substrate is illuminated on a first side and a second side, the first side configured to receive incident charged particles from the sample and the second side being opposite to the first side.

36. The method of any one of clauses 30-35, wherein the substrate is illuminated by an external source that comprises a laser, an LED, or an electron beam source.

37. The method of any one of clauses 30-36, wherein the substrate is illuminated in a region between the pickup point and a transistor arranged between adjacent sensing elements of the detector.

38. The method of any one of clauses 30-37, further comprising:
generating a primary charged particle beam; and
scanning the primary charged particle beam over the sample.

39. The method of any one of clauses 30-38, further comprising:
determining a first number of carriers generated in the substrate from illuminating the substrate; and
determining a second number of carriers generated in the substrate from the charged particle interacting with the substrate.

40. The method of clause 39, wherein the second number of carriers is determined by subtracting the first number of carriers from a third number of carriers, the third number of carriers including a total number of carriers collected at the pickup point.

41. A non-transitory computer-readable medium storing a set of instructions that are executable by one or more processors of a charged particle beam apparatus to cause the charged particle beam apparatus to perform a method comprising:
illuminating a substrate that includes a portion of a detector to cause generation of a stream of carriers in the substrate, wherein the substrate is configured to receive a charged particle emitted from a sample,
wherein the charged particle interacts with the substrate to trigger generation of numerous carriers in the substrate; and detecting carriers via a pickup point on the substrate.

42. The medium of clause 41, wherein the set of instructions are executable to cause the charged particle beam apparatus to:
illuminate the substrate continuously during a period.

43. The medium of clause 41 or clause 42, wherein the set of instructions are executable to cause the charged particle beam apparatus to:
illuminate the substrate on a first side that is configured to receive incident charged particles from the sample.

44. The medium of clause 41 or clause 42, wherein the set of instructions are executable to cause the charged particle beam apparatus to:
illuminate the substrate on a second side, the second side being opposite to a first side that is configured to receive incident charged particles from the sample.

45. The medium of clause 41 or clause 42, wherein the set of instructions are executable to cause the charged particle beam apparatus to:
illuminate the substrate on a first side and a second side, the first side configured to receive incident charged particles from the sample and the second side being opposite to the first side.

46. The medium of any one of clauses 41-45, wherein the set of instructions are executable to cause the charged particle beam apparatus to:
illuminate the substrate in a region between the pickup point and a transistor arranged between adjacent sensing elements of the detector.

47. The medium of any one of clauses 41-46, wherein the set of instructions are executable to cause the charged particle beam apparatus to:
generate a primary charged particle beam; and
scan the primary charged particle beam over the sample.

48. The medium of any one of clauses 41-47, wherein the set of instructions are executable to cause the charged particle beam apparatus to:
determine a first number of carriers generated in the substrate from illuminating the substrate; and
determine a second number of carriers generated in the substrate from the charged particle interacting with the substrate.

49. The medium of clause 48, wherein the second number of carriers is determined by subtracting the first number of carriers from a third number of carriers, the third number of carriers including a total number of carriers collected at the pickup point.

50. A charged particle detector comprising:
a plurality of sensing elements formed in a substrate, wherein a sensing element of the plurality of sensing elements is formed of a first region on a first side of the substrate, and a second region on a second side of the substrate, the second side being opposite to the first side;
a plurality of third regions formed on the second side of the substrate, the third regions including one or more circuit components; and
a fourth region formed on the second side of the substrate, the fourth region being configured to collect carriers generated in the sensing element, wherein
the second region includes a differential gradient region between a periphery of the sensing element and the fourth region.

51. The charged particle detector of clause 50, wherein the differential gradient is formed in a direction perpendicular to a thickness direction of the substrate.

52. The charged particle detector of clause 50 or clause 51, wherein the differential gradient is continuous from the periphery of the sensing element to the fourth region.

53. The charged particle detector of any one of clauses 50-52, wherein
the first region includes semiconductor material of a first conductivity,
the second region includes semiconductor material of a second conductivity,
the plurality of third regions include semiconductor material of the first conductivity, and
the fourth region includes semiconductor material of the second conductivity.

54. The charged particle detector of any one of clauses 50-53, wherein
the first region includes p type semiconductor,
the second region includes n type semiconductor,
the plurality of third regions include p type semiconductor, and
the fourth region includes n type semiconductor.

55. The charged particle detector of any one of clauses 50-54, wherein the differential gradient includes
a plurality of regions with gradually decreasing doping density toward the fourth region.

56. The charged particle detector of any one of clauses 50-55, wherein the differential gradient includes regions of differing density of n type semiconductor.

57. The charged particle detector of any one of clauses 50-56, wherein the plurality of third regions include transistors, and the differential gradient overlaps with the transistors.

58. The charged particle detector of any one of clauses 50-57, wherein the differential gradient substantially fills the second region.

59. The charged particle detector of any one of clauses 1-5, wherein the array of fourth regions is connected by a bridge portion.

60. The method of any one of clauses 30-35, wherein the substrate is illuminated by an external radiation source.

61. The method of clause 32, wherein the period is a scan of the sample.

It will be appreciated that the embodiments of the present disclosure are not limited to the exact construction that has been described above and illustrated in the accompanying drawings, and that various modifications and changes can be made without departing from the scope thereof.

1. A charged particle detector comprising:
a plurality of sensing elements formed in a substrate, wherein a sensing element of the plurality of sensing elements is formed of a first region on a first side of the substrate, and a second region on a second side of the substrate, the second side being opposite to the first side;
a plurality of third regions formed on the second side of the substrate, the third regions including one or more circuit components; and
an array of fourth regions formed on the second side of the substrate, the array of fourth regions being between adjacent third regions.

2. The charged particle detector of claim 1, wherein
the first region includes semiconductor material of a first conductivity,
the second region includes semiconductor material of a second conductivity,
the third region includes semiconductor material of the first conductivity, and
the array of fourth regions includes semiconductor material of the second conductivity.

3. The charged particle detector of claim 1, wherein
the first region includes p type semiconductor,
the second region includes n type semiconductor,
the third region includes p type semiconductor, and
the fourth region includes n type semiconductor.

4. The charged particle detector of claim 1, wherein the second region is adjacent to the first region.

5. The charged particle detector of claim 1, wherein the sensing element includes a PIN diode.

6. The charged particle detector of claim 1, wherein the array of fourth regions is connected by a wiring path.

7. The charged particle detector of claim 1, wherein the array of fourth regions is connected by a bridge portion.

8. The charged particle detector of claim 1, wherein the array of fourth regions includes electrodes configured to collect carriers generated in the sensing element.

9. The charged particle detector of claim 1, wherein the one or more circuit components include transistors.

10. A non-transitory computer-readable medium storing a set of instructions that are executable by one or more processors of a charged particle beam apparatus to cause the charged particle beam apparatus to perform a method comprising:
illuminating a substrate that includes a portion of a detector to cause generation of a stream of carriers in the substrate, wherein the substrate is configured to receive a charged particle emitted from a sample, wherein the charged particle interacts with the substrate to trigger generation of numerous carriers in the substrate; and
detecting carriers via a pickup point on the substrate.

11. The medium of claim 10, wherein the set of instructions are executable to cause the charged particle beam apparatus to:
illuminate the substrate continuously during a period.

12. The medium of claim 10, wherein the set of instructions are executable to cause the charged particle beam apparatus to:
illuminate the substrate on a first side that is configured to receive incident charged particles from the sample.

13. The medium of claim 10, wherein the set of instructions are executable to cause the charged particle beam apparatus to:
illuminate the substrate on a second side, the second side being opposite to a first side that is configured to receive incident charged particles from the sample.

14. The medium of claim 10, wherein the set of instructions are executable to cause the charged particle beam apparatus to:
illuminate the substrate on a first side and a second side, the first side configured to receive incident charged particles from the sample and the second side being opposite to the first side.

15. The medium of claim 10, wherein the set of instructions are executable to cause the charged particle beam apparatus to:
illuminate the substrate in a region between the pickup point and a transistor arranged between adjacent sensing elements of the detector.

16. The medium of claim 10, wherein the set of instructions are executable to cause the charged particle beam apparatus to:
generate a primary charged particle beam; and
scan the primary charged particle beam over the sample.

17. The medium of claim 10, wherein the set of instructions are executable to cause the charged particle beam apparatus to:
determine a first number of carriers generated in the substrate from illuminating the substrate; and
determine a second number of carriers generated in the substrate from the charged particle interacting with the substrate.

18. The medium of claim 17, wherein the second number of carriers is determined by subtracting the first number of carriers from a third number of carriers, the third number of carriers including a total number of carriers collected at the pickup point.

19. A method for detecting charged particles comprising:
illuminating a substrate that includes a portion of a detector to cause generation of a stream of carriers in the substrate;
receiving, at the substrate, a charged particle emitted from a sample, wherein the charged particle interacts with the substrate to trigger generation of numerous carriers in the substrate; and
detecting carriers via a pickup point on the substrate.

20. The method of claim 19, wherein the substrate includes a PIN diode and illuminating the substrate causes generation of a constant stream of electron hole pairs in a depletion region of the PIN diode.
